(19) United States
(12) Patent Application Publication
(10) Pub. No.: US 2026/0215137 A1
(43) Pub. Date: Jul. 23, 2026

(54) LENS ASSEMBLY, DISPLAY DEVICE COMPRISING LENS ASSEMBLY, AND ELECTRONIC DEVICE

(71) Applicant: Samsung Display Co., Ltd., Yongin-si (KR)

(72) Inventor: Yong Kyu KANG, Yongin-si (KR)

(21) Appl. No.: 19/287,518

(22) Filed: Jul. 31, 2025

(30) Foreign Application Priority Data
Jan. 22, 2025 (KR) 10-2025-0009634

(51) Int. Cl. H10K 59/80; G02B 3/00; G02B 5/30

(52) U.S. Cl. CPC H10K 59/879; G02B 3/0012; G02B 3/0037; G02B 5/3025

(57) ABSTRACT

The present disclosure provides a lens assembly including an incident side on which light is incident and an exit side opposite to the incident side. The lens assembly includes a first lens disposed adjacent to the incident side; a second lens on the first lens; and a third lens on the second lens and adjacent to the exit side. The first lens has a first lens material injection part, the second lens has a second lens material injection part, the third lens has a third lens material injection part, and the first lens material injection part, the second lens material injection part and the third lens material injection part, are at different positions from each other in a plan view.

### CROSS-REFERENCE TO RELATED APPLICATION

This application claims priority to and the benefit of Korean Patent Application No. 10-2025-0009634 filed in the Korean Intellectual Property Office on Jan. 22, 2025, the entire disclosure of which is incorporated by reference herein.

### BACKGROUND

### 1. Field

The present disclosure relates to a lens assembly, a display device comprising the lens assembly, and an electronic device.

### 2. Description of the Related Art

As information technology has developed, importance of a display device, which is a connection medium between a user and information, has been highlighted. Accordingly, research and development on a display device are continuously being conducted.

Recently, a head mounted display (HMD) has been developed. The head-mounted display device is a display device that implements virtual reality (VR), augmented reality (AR), or mixed reality (MR) in which a user wears the display device in the form of glasses or a helmet to form a focus at a location close to the user's eyes. A high-resolution panel is applied to the head-mounted display device, and a pancake lens for high immersion may be applied.

### SUMMARY

Embodiments of the present disclosure provide a lens assembly to improve display quality, a display device including the lens assembly, and an electronic device.

Embodiments of the present disclosure provide a lens assembly, a display device including the lens assembly, and an electronic device to reduce a risk of occurrence by birefringence.

One or more embodiments of the present disclosure provide a lens assembly including an incident side on which light is incident and an exit side opposite to the incident side. The lens assembly includes a first lens adjacent to the incident side; a second lens on the first lens; and a third lens on the second lens and adjacent to the exit side. The first lens has a first lens material injection part, the second lens has a second lens material injection part, the third lens has a third lens material injection part, and the first lens material injection part, the second lens material injection part, and the third lens material injection part are at different positions from each other in a plan view.

According to one or more embodiments, a first virtual line passing through a center of the third lens material injection part and a center of the third lens, and a second virtual line passing through a center of the second lens and a center of the second lens may form a first angle, and the first angle may be 170° to 180°.

According to one or more embodiments, the first virtual line and a third virtual line passing through a center of the first lens material injection part and a center of the first lens may form a second angle, and the second angle may be 35° to 55°.

According to one or more embodiments, the first angle may be 180°, and the second angle may be 45°.

According to one or more embodiments, the second angle may be 45° or 315° with respect to a clockwise direction.

According to one or more embodiments, the first virtual line vertically may pass through the third lens material injection part, the second virtual line vertically may pass through the second lens material injection part, and the third virtual line vertically may pass through the first lens material injection part.

According to one or more embodiments, the second lens material injection part may be on an opposite side of the third lens material injection part, in a plan view.

According to one or more embodiments, the first lens material injection part may be spaced from the third lens material injection part along a periphery of the first lens or the third lens, in a plan view.

According to one or more embodiments, the first lens material injection part may be at left or right of the third lens material injection part along a periphery of the first lens or the third lens, in a plan view.

According to one or more embodiments, each of the first lens, the second lens, and the third lens may be formed by an injection molding process, the first lens material injection part may correspond to an injection part into which a material forming the first lens is injected in the injection process, the second lens material injection part may correspond to an injection part into which a material forming the second lens is injected in the injection process, and the third lens material injection part may correspond to an injection part into which a material forming the third lens is injected in the injection process.

According to one or more embodiments, the lens assembly may further include: a first polarization layer between the incident side and the first lens; a first quarter wave plate on the first polarization layer; a partially reflective mirror layer on the first quarter wave plate; a second quarter wave plate between the second lens and the third lens; and a second polarization layer between the second quarter wave plate and the third lens.

One or more embodiments of the present disclosure provide a display device including: a display panel; and a lens assembly on the display panel, including an incident side on which light provided from the display panel is incident and an exit side opposite to the incident side. The lens assembly includes: a first lens adjacent to the incident side; a second lens on the first lens; and a third lens on the second lens and adjacent to the exit side. The first lens has a first lens material injection part, the second lens has a second lens material injection part, the third lens has a third lens material injection part, and the first lens material injection part, the second lens material injection part, and the third lens material injection part are at different positions from each other in a plan view.

According to one or more embodiments, a first virtual line passing through a center of the third lens material injection part and a center of the third lens, and a second virtual line passing through a center of the second lens and a center of the second lens may form a first angle, the first virtual line and a third virtual line passing through a center of the first lens material injection part and a center of the first lens may form a second angle, the first angle may be 170° to 180°, and the second angle may be 35° to 55°.

According to one or more embodiments, the first angle may be 180°, the second angle may be 45° or 315° with respect to a clockwise direction, the first virtual line vertically may pass through the third lens material injection part, the second virtual line vertically may pass through the second lens material injection part, the third virtual line vertically may pass through the first lens material injection part.

According to one or more embodiments, the second lens material injection part may be on an opposite side of the third lens material injection part, in a plan view, the first lens material injection part may be spaced from the third lens material injection part along a periphery of the first lens or the third lens, in a plan view.

According to one or more embodiments, each of the first lens, the second lens, and the third lens may be formed by an injection molding process, the first lens material injection part may correspond to an injection part into which a material forming the first lens is injected in the injection process, the second lens material injection part may correspond to an injection part into which a material forming the second lens is injected in the injection process, and the third lens material injection part may correspond to an injection part into which a material forming the third lens is injected in the injection process.

According to one or more embodiments, the lens assembly may further include: a first polarization layer between the incident side and the first lens; a first quarter wave plate on the first polarization layer; a partially reflective mirror layer on the first quarter wave plate; a second quarter wave plate between the second lens and the third lens; and a second polarization layer between the second quarter wave plate and the third lens.

One or more embodiments of the present disclosure provide an electronic device including: a display device; and a processor. The display device includes: a display panel; and a lens assembly on the display panel, including an incident side on which light provided from the display panel is incident and an exit side opposite to the incident side. The lens assembly includes: a first lens adjacent to the incident side; a second lens on the first lens; and a third lens on the second lens and adjacent to the exit side. The first lens has a first lens material injection part, the second lens has a second lens material injection part, the third lens has a third lens material injection part, and the first lens material injection part, the second lens material injection part, and the third lens material injection part are at different positions from each other in a plan view.

According to one or more embodiments, each of the first lens, the second lens, and the third lens may be formed by an injection molding process, the first lens material injection part may correspond to an injection part into which a material forming the first lens is injected in the injection process, the second lens material injection part may correspond to an injection part into which a material forming the second lens is injected in the injection process, the third lens material injection part may correspond to an injection part into which a material forming the third lens is injected in the injection process, a first virtual line passing through a center of the third lens material injection part and a center of the third lens, and a second virtual line passing through a center of the second lens and a center of the second lens may form a first angle, the first virtual line and a third virtual line passing through a center of the first lens material injection part and a center of the first lens may form a second angle, the first angle may be 170° to 180°, and the second angle may be 35° to 55°.

According to one or more embodiments, each of the first lens, the second lens, and the third lens may be formed by an injection molding process, the first lens material injection part may correspond to an injection part into which a material forming the first lens is injected in the injection process, the second lens material injection part may correspond to an injection part into which a material forming the second lens is injected in the injection process, the third lens material injection part may correspond to an injection part into which a material forming the third lens is injected in the injection process, the second lens material injection part may be on an opposite side of the third lens material injection part, in a plan view, and the first lens material injection part may be spaced from the third lens material injection part along a periphery of the first lens or the third lens, in a plan view.

According to embodiments of the present disclosure, a lens assembly to improve display quality, a display device including the lens assembly, and an electronic device may be provided.

According to embodiments of the present disclosure, a lens assembly, a display device including the lens assembly, and an electronic device to reduce a risk of birefringence occurring may be provided.

### BRIEF DESCRIPTION OF THE DRAWINGS

FIG. 1 illustrates a schematic block diagram of a display device according to one or more embodiments.

FIG. 2 illustrates a schematic block diagram of one of sub-pixels of FIG. 1 according to one or more embodiments.

FIG. 3 illustrates a circuit diagram illustrating one or more embodiments of the sub-pixel shown in FIG. 2.

FIG. 4 illustrates a schematic top plan view of a display panel of FIG. 1 according to one or more embodiments.

FIG. 5 illustrates a schematic exploded perspective view of a portion of a display panel of FIG. 4.

FIG. 6 illustrates a schematic top plan view of one of pixels of FIG. 5 according to one or more embodiments.

FIG. 7 illustrates a schematic cross-sectional view taken along the line I-I′ of FIG. 6 according to one or more embodiments.

FIG. 8 illustrates a schematic cross-sectional view taken along the line I-I′ of FIG. 6 according to one or more embodiments.

FIG. 9 illustrates a schematic enlarged view of an area “A” of FIG. 8.

FIG. 10 illustrates a cross-sectional view of a portion of a light emitting structure included in one of first to third light emitting elements of FIG. 7 or FIG. 8 according to one or more embodiments.

FIG. 11 illustrates a cross-sectional view of a portion of a light emitting structure included in one of first to third light emitting elements of FIG. 7 or FIG. 8 according to one or more embodiments.

FIG. 12 illustrates a schematic top plan view of one of pixels of FIG. 5 according to one or more embodiments.

FIG. 13 illustrates a schematic top plan view of one of pixels of FIG. 5 according to one or more embodiments.

FIG. 14 illustrates a schematic cross-sectional view of the display device according to one or more embodiments.

FIGS. 15 and 16 illustrate schematic plan views showing the placement of a first lens, a second lens, and a third lens according to one or more embodiments.

FIG. 17 illustrates a schematic block diagram of an electronic device according to one or more embodiments.

FIG. 18 illustrates a schematic diagram of an electronic device according to various embodiments.

### DETAILED DESCRIPTION

Hereinafter, example embodiments of the present disclosure will be described in detail with reference to the accompanying drawings. The following description is intended to provide only a sufficient disclosure to enable the understanding of the operation of the present disclosure, and any other disclosure is omitted to avoid obscuring the scope of the present disclosure. In addition, the present disclosure may be embodied in different forms and is not limited to the embodiments set forth herein. The embodiments described herein are provided for the purpose of describing the technical concept of the present disclosure in sufficient detail for those skilled in the art to easily practice it.

Throughout the specification, when it is described that an element is “connected” to another element, this includes not only being “directly connected”, but also being “indirectly connected” with another device in between. The terms used herein are for the purpose of describing specific embodiments and are not intended to limit the scope of the present disclosure. Throughout the specification, unless explicitly described to the contrary, the word “comprise” and variations such as “comprises” or “comprising” will be understood to imply the inclusion of stated elements but not the exclusion of any other elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, etc. may be used herein to describe various constituent elements, these constituent elements should not be limited by these terms. These terms are used to distinguish one constituent element from another. Thus, a first constituent element discussed below could be termed a second constituent element without departing from the teachings of the present disclosure.

Spatially relative terms, such as “beneath,” “below,” “lower,” “above,” “upper,” and/or the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

Various embodiments are described herein with reference to sectional illustrations that are schematic illustrations of idealized embodiments. As such, variations from the shapes of the illustrations as a result, for example, of manufacturing techniques and/or tolerances, are to be expected. Thus, example embodiments disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

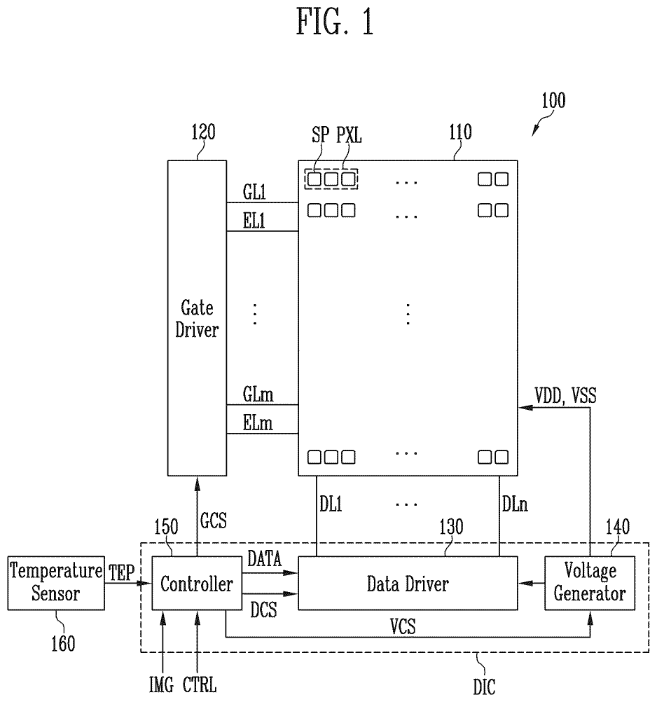

FIG. 1 illustrates a schematic block diagram of a display device according to one or more embodiments.

Referring to FIG. 1, the display device 100 may include a display panel 110, a gate driver 120, a data driver 130, a voltage generator 140, a controller 150, and a temperature sensor 160.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, the sub-pixels SP may respectively generate light of a specific color, such as red, green, blue, cyan, magenta, yellow, and/or the like. Two or more of the sub-pixels SP may configure one pixel PXL. For example, as shown in FIG. 1, three sub-pixels may configure one pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In one or more embodiments, the gate control signal GCS may include a start signal indicating the start of each frame, a horizontal synchronization signal for outputting gate signals in synchronization with the timing at which data signals are applied, and/or the like.

In one or more embodiments, first to m-th light emitting control lines EL1 to ELm connected to the sub-pixels SP in a row direction may be further provided. In this case, the gate driver 120 may include a light emitting control driver configured to control the first to m-th light emitting control lines EL1 to ELm, and the light emitting control driver may operate under the control of the controller 150.

The gate driver 120 may be disposed on one side of the display panel 110. However, the present disclosure is not limited thereto. For example, the gate driver 120 may be divided into two or more physically and/or logically separated drivers, and the drivers may be disposed on one side of the display panel 110 and the other side of the display panel 110 opposite to the one side. As described above, the gate driver 120 may be disposed around the display panel 110 in various forms according to the one or more embodiments,

The data driver 130 is connected to the sub-pixels SP arranged in a column direction through the first to n-th data lines DL1 to DLn. The data driver 130 receives image data (DATA) and data control signal DCS from the controller 150. The data driver 130 operates in response to the data control signal DCS. In one or more embodiments, the data control signal DCS may include a source start pulse, a source shift clock, a source output enable signal, and/or the like.

The data driver 130 may use voltages from the voltage generator 140 to apply data signals having grayscale voltages corresponding to the image data (DATA) to the first to n-th data lines DL1 to DLn. When a gate signal is applied to each of the first to m-th gate lines GL1 to GLm, data signals corresponding to the image data DATA may be applied to the data lines DL1 to DLm. Accordingly, the corresponding sub-pixels SP may generate light corresponding to the data signals. Accordingly, an image is displayed on the display panel 110.

In one or more embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to constituent elements of the display device 100. For example, the voltage generator 140 may be configured to generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the first power voltage VDD. In one or more embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation to sense electrical characteristics of transistors and/or light emitting elements of the sub-pixels SP, a suitable reference voltage (e.g., a predetermined reference voltage) may be applied to the first to n-th data lines DL1 to DLn, and the voltage generator 140 may generate the reference voltage.

The controller 150 controls various operations of the display device 100. The controller 150 receives input image data IMG and a control signal CTRL for controlling the display of the input image data, from the outside. The controller 150 may provide the gate control signal GCS, the data control signal DCS, and the voltage control signal VCS in response to the control signal CTRL.

The controller 150 may convert the input image data IMG to be suitable for the display device 100 or the display panel 110 to output the image data DATA. In one or more embodiments, the controller 150 may output the image data DATA by aligning the input image data IMG to be suitable for the sub-pixels SP of a row unit.

Two or more components of the data driver 130, the voltage generator 140, and the controller 150 may be mounted on one integrated circuit (IC). As shown in FIG. 1, the data driver 130, the voltage generator 140, and the controller 150 may be included in a driver integrated circuit DIC. In this case, the data driver 130, the voltage generator 140, and the controller 150 may be functionally separate components within one driver integrated circuit DIC. In one or more embodiments, at least one of the data driver 130, the voltage generator 140, and the controller 150 may be provided as a component separated from the driver integrated circuit DIC.

The display device 100 may include at least one temperature sensor 160. The temperature sensor 160 is configured to sense a surrounding temperature and generate temperature data TEP representing the sensed temperature. In one or more embodiments, the temperature sensor 160 may be disposed to be adjacent to the display panel 110 and/or the driver integrated circuit DIC.

The controller 150 may control various operations of the display device 100 in response to the temperature data TEP. In one or more embodiments, the controller 150 may adjust the luminance of an image outputted from the display panel 110 in response to the temperature data TEP. For example, the controller 150 may control the data signals and the first and second power voltages VDD and VSS by controlling components such as the data driver 130 and/or the voltage generator 140.

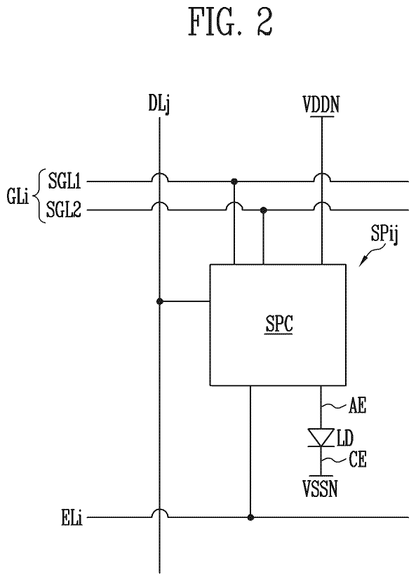

FIG. 2 illustrates a schematic block diagram of one of sub-pixels of FIG. 1 according to one or more embodiments. In FIG. 2, among the sub-pixels SP of FIG. 1, a sub-pixel SPij disposed in an i-th row (i is an integer greater than or equal to 1 and less than or equal to m) and a j-th column (j is an integer greater than or equal to 1 and less than or equal to n) is illustrated as an example.

Referring to FIG. 2, the sub-pixel SPij may include a sub-pixel circuit SPC and a light emitting element LD.

The light emitting element LD is connected between the first power voltage node VDDN and a second power voltage node VSSN. In this case, the first power voltage node VDDN is a node that transmits the first power voltage VDD of FIG. 1, and the second power voltage node VSSN is a node that transmits the second power voltage VSS of FIG. 1. The light emitting device LD according to the present disclosure may be an organic light emitting device (OLED). However, the present disclosure is not limited thereto.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi from among the first to m-th gate lines GL1 to GLm of FIG. 1, an i-th light emitting control line ELi from among the first to m-th light emitting control lines EL1 to ELm of FIG. 1, and a j-th data line DLj from among the first to n-th data lines DL1 to DLn of FIG. 1. The sub-pixel circuit SPC is configured to control the light emitting element LD according to signals received through these signal lines.

The sub-pixel circuit SPC may operate in response to a gate signal received through the i-th gate line GLi. The i-th gate line GLi may include one or more sub-gate lines. In one or more the embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As such, when the i-th gate line GLi includes two or more sub-gate lines, the sub-pixel circuit SPC may operate in response to gate signals received through the corresponding sub-gate lines.

The sub-pixel circuit SPC may operate in response to a light emitting control signal received through the i-th light emitting control line ELi. In the one or more embodiments, the i-th light emitting control line ELi may include one or more sub-light emitting control lines. When the i-th light emitting control line ELi includes two or more sub-light emitting control lines, the sub-pixel circuit SPC may operate in response to light emitting control signals received through the corresponding sub-light emitting control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. In response to the light emitting control signal received through the i-th light emitting control line ELi, the sub-pixel circuit SPC may adjust the current flowing from the first power voltage node VDDN to the second power voltage node VSSN through the light emitting element LD according to the stored voltage. Accordingly, the light emitting element LD may generate light of luminance corresponding to the data signal.

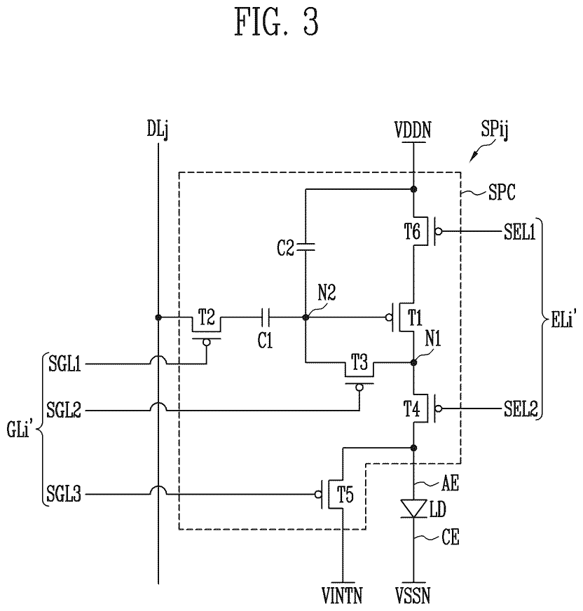

FIG. 3 is a circuit diagram illustrating an embodiment of the sub-pixel shown in FIG. 2.

Referring to FIG. 3, a sub-pixel SPij may include a sub-pixel circuit SPC and a light emitting element LD.

The sub-pixel circuit SPC may be connected to an ith gate line GLi′, an ith emission control line ELi′, and a jth data line DLj. When comparing the ith gate line GLi′ with the ith gate line GLi shown in FIG. 2, the ith gate line GLi′ may further include a third sub-gate line SGL3. When comparing the ith emission control line ELi′ with the ith emission control line ELi shown in FIG. 2, the ith emission control line ELi′ may include a first sub-emission control line SEL1 and a second sub-emission control line SEL2.

The sub-pixel circuit SPC may include first to sixth transistors T1 to T6 and first and second capacitors C1 and C2.

The first transistor T1 may be connected between a first power voltage node VDDN and a first node N1. A gate of the first transistor T1 may be connected to a second node N2, and accordingly, the first transistor T1 may be turned on according to a voltage level of the second node N2. The first transistor T1 may be designated as a driving transistor.

The second transistor T2 may be connected between the jth data line DLj and the second node N2. A gate of the second transistor T2 may be connected to a first sub-gate line SGL1, and accordingly, the second transistor T2 may be turned on in response to a gate signal of the first sub-gate line SGL1. The second transistor T2 may be designated as a switching transistor.

The third transistor T3 may be connected between the first node N1 and the second node N2. A gate of the third transistor T3 may be connected to a second sub-gate line SGL2, and accordingly, the third transistor T3 may be turned on in response to a gate signal of the second sub-gate line SGL2 and diode-connect the first transistor T1.

The fourth transistor T4 may be connected between the first node N1 and an anode electrode AE of the light emitting element LD. A gate of the fourth transistor T4 may be connected to the second sub-emission control line SEL2, and accordingly, the fourth transistor T4 may be turned on in response to an emission control signal of the second sub-emission control line SEL2.

The fifth transistor T5 may be connected between the anode electrode AE of the light emitting element LD and an initialization voltage node VINTN. The initialization voltage node VINTN may be configured to transfer an initialization voltage. In one or more embodiments the initialization voltage may be provided by the voltage generator 140 shown in FIG. 1. In one or more embodiments, the initialization voltage may be provided by an external device of the display device 100. A gate of the fifth transistor T5 may be connected to the third sub-gate line SGL3, and accordingly, the fifth transistor T5 may be turned on in response to a gate signal of the third sub-gate line SGL3.

The sixth transistor T6 may be connected between the first power voltage node VDDN and the first transistor T1. A gate of the sixth transistor T6 may be connected to the first sub-emission control line SEL1, and accordingly, the sixth transistor T6 may be turned on in response to an emission control signal of the first sub-emission control line SEL1.

The first capacitor C1 may be connected between the second transistor T2 and the second node N2. The second capacitor C2 may be connected between the first power voltage node VDDN and the second node N2.

As such, the sub-pixel circuit SPC may include the first to sixth transistors T1 to T6 and the first and second capacitors C1 and C2. However, the present disclosure is not limited thereto. The sub-pixel circuit SPC may be implemented as any one of various types of circuits each including a plurality of transistors and one or more capacitors. For example, the sub-pixel circuit SPC may include two transistors and one capacitor. In accordance with one or more embodiments of the sub-pixel circuit SPC, the number of sub-gate lines included in the ith gate line GLi′ and the number of sub-emission control lines included in the ith emission control line ELi′ may vary.

The first to sixth transistors T1 to T6 may be P-type transistors. Each of the first to sixth transistors T1 to T6 may be a Metal Oxide Semiconductor Field Effect Transistor (MOSEFT). However, the present disclosure is not limited thereto. For example, at least one of the first to sixth transistors T1 to T6 may be replaced with an N-type transistor.

In one or more embodiments, the first to sixth transistors T1 to T6 may include an amorphous silicon semiconductor, a monocrystalline silicon semiconductor, a polycrystalline silicon semiconductor, an oxide semiconductor, and/or the like.

The light emitting element LD may include the anode electrode AE, a cathode electrode CE, and a light emitting layer. The light emitting layer may be disposed between the anode electrode AE and the cathode electrode CE. After a data signal transferred through the jth data line DLj is reflected on a voltage of the second node N2, the fourth and sixth transistors T4 and T6 may be turned on when the emission control signals of the first and second sub-emission control lines SEL1 and SEL2 are enabled to a low level. The first transistor T1 may be turned on according to the voltage of the second node N2, and accordingly, a current may flow from the first power voltage node VDDN to a second power voltage node VSSN. The light emitting element LD may emit light according to an amount of the current flowing from the first power voltage node VDDN to the second power voltage node VSSN.

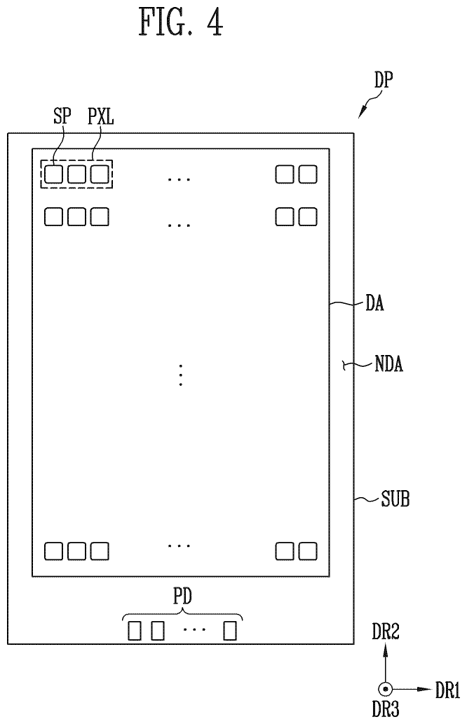

FIG. 4 illustrates a schematic top plan view of a display panel of FIG. 1 according to one or more embodiments.

Referring to FIG. 4, an embodiment DP of the display panel 110 of FIG. 1 may include a display area DA and a non-display area NDA disposed around the display area DA along an edge or a periphery of the display area DA. The display panel DP displays an image through the display area DA. The non-display area NDA is disposed around the display area DA.

The display panel DP may include a substrate SUB, sub-pixels SP, and pads PD.

When the display panel DP is used as a display screen for a head mounted display (HMD), a virtual reality (VR) device, a mixed reality (MR) device, and/or an augmented reality (AR) device, the display panel DP may be positioned very close to the user's eyes. In this case, the sub-pixels SP with relatively high integration are required. In order to increase the integration of the sub-pixels SP, the substrate SUB may be provided as a silicon substrate. The sub-pixels SP and/or the display panel DP may be formed on the substrate SUB, which is a silicon substrate. The display device 100 (see FIG. 1) including the display panel DP formed on the substrate SUB, which is a silicon substrate, may be referred to as an OLED on silicon (OLEDoS) display device.

The sub-pixels SP are disposed in the display area DA on the substrate SUB. The sub-pixels SP may be arranged in a matrix format along a first direction DR1 and a second direction DR2 that intersects the first direction DR1. For example, the sub-pixels SP may be arranged along rows and columns of a matrix along the first direction DR1 and the second direction DR2. However, the present disclosure is not limited thereto. For example, the sub-pixels SP may be arranged in a zigzag form along first direction DR1 and second direction DR2. For example, the sub-pixels SP may be disposed in a PENTILE® shape. PENTILE® is a registered trademark of Samsung Display Co., Ltd., Republic of Korea. The first direction DR1 may be a row direction, and the second direction DR2 may be a column direction. In addition, a third direction DR3 may be a direction in which light is emitted from the display panel DP.

Two or more of the plurality of sub-pixels SP may configure one pixel PXL.

A constituent element to control the sub-pixels SP may be disposed in the non-display area NDA on the substrate SUB. For example, wires connected to the sub-pixels SP, such as the first to m-th gate lines GL1 to GLm and the first to n-th data lines DL1 to DLn of FIG. 1, may be disposed in the non-display area NDA.

At least one of the gate driver 120, the data driver 130, the voltage generator 140, the controller 150, and the temperature sensor 160 in FIG. 1 may be integrated in the non-display area NDA of the display panel DP. In one or more embodiments, the gate driver 120 of FIG. 1 may be mounted on the display panel DP, and may be disposed in the non-display area NDA. In one or more embodiments, the gate driver 120 may be implemented as an integrated circuit separated from the display panel DP. In one or more embodiments, the temperature sensor 160 may be disposed in the non-display area NDA to detect the temperature of the display panel DP.

The pads PD are disposed in the non-display area NDA on the substrate SUB. The pads PD may be electrically connected to the sub-pixels SP through wires. For example, the pads PD may be connected to the sub-pixels SP through the first to n-th data lines DL1 to DLn.

The pads PD may interface the display panel DP to other constituent elements of the display device 100 (see FIG. 1). In one or more embodiments, voltages and signals required for operations of constituent elements included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In one or more embodiments, a circuit board may be electrically connected to the pads PD using a conductive adhesive member, such as an anisotropic conductive film. In this case, the circuit board may be a flexible printed circuit board (FPCB) or a flexible film made of a flexible material. The driver integrated circuit DIC may be mounted on the circuit board to be electrically connected to the pads PD.

In one or more embodiments, the display area DA may have various shapes. The display area DA may have a closed-loop shape including sides of a straight line and/or a curved line. For example, the display area DA may have shapes such as a polygonal shape, a circular shape, a semicircular, or an elliptical shape.

In one or more embodiments, the display panel DP may have a flat display surface. In one or more embodiments, the display panel DP may have a display surface that is at least partially round. In one or more embodiments, the display panel DP may be bendable, foldable, and/or rollable. In these cases, the display panel DP and/or the substrate SUB may include materials with flexible properties.

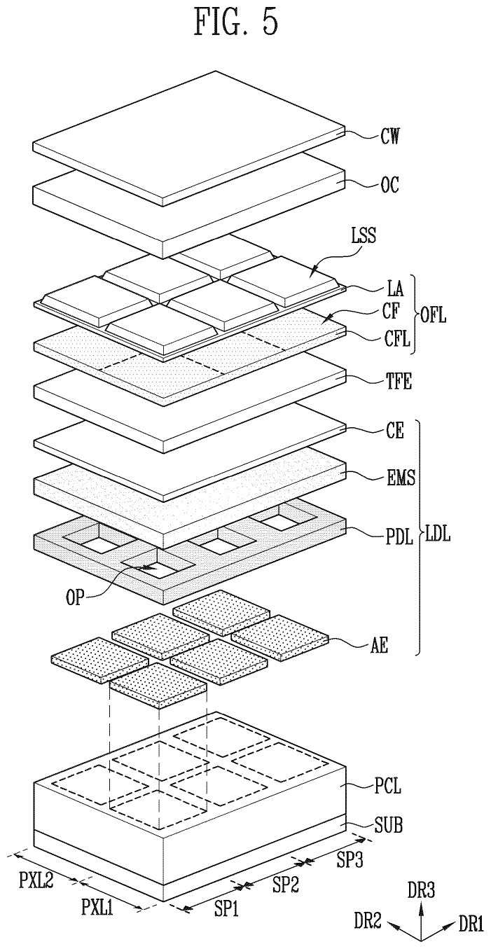

FIG. 5 illustrates a schematic exploded perspective view of a portion of a display panel of FIG. 4. In FIG. 5, for clear and concise description, a portion of the display panel DP corresponding to two pixels PXL1 and PXL2 from among the pixels PXL of FIG. 4 is schematically shown. Portions of the display panel DP corresponding to the remaining pixels may be similarly configured.

Referring to FIG. 4 and FIG. 5, each of the first and second pixels PXL1 and PXL2 may include first to third sub-pixels SP1, SP2, and SP3. However, the present disclosure is not limited thereto. For example, each of the first and second pixels PXL1 and PXL2 may include four sub-pixels, or two sub-pixels.

In FIG. 5, the first to third sub-pixels SP1, SP2, and SP3 are shown to have quadrangular shapes and have the same sizes when viewed in the third direction DR3 (e.g., in a plan view) crossing the first and second directions DR1 and DR2. However, the present disclosure is not limited thereto. The first to third sub-pixels SP1, SP2, and SP3 may be modified to have various shapes.

The display panel DP may include a substrate SUB, a pixel circuit layer PCL, a light emitting element layer LDL, an encapsulation layer TFE, an optical functional layer OFL, an overcoat layer OC, and a cover window CW.

In one or more embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, an epitaxial layer, a silicon on Insulator (SOI) layer, and/or a semiconductor on insulator (SeOI) layer. In one or more embodiments, the substrate SUB may include a glass substrate. In still other embodiments, the substrate SUB may include a polyimide (PI) substrate.

The pixel circuit layer PCL is disposed on the substrate SUB. The substrate SUB and/or the pixel circuit layer PCL may include insulating layers and conductive patterns disposed between the insulating layers. The conductive patterns of the pixel circuit layer PCL may function as at least some of circuit elements, wires, and/or the like. The conductive patterns may include copper, but the present disclosure is not limited thereto.

The circuit elements may include the sub-pixel circuit SPC (see FIG. 2) for each of first to third sub-pixels SP1, SP2, and SP3. The sub-pixel circuit SPC may include transistors and one or more capacitors. Each transistor may include a semiconductor portion including a source region, a drain region, and a channel region, and a gate electrode overlapping the semiconductor portion. In one or more embodiments, when the substrate SUB is provided as a silicon substrate, the semiconductor portion may be included in the substrate SUB, and the gate electrode may be included in the pixel circuit layer PCL as the conductive pattern of the pixel circuit layer PCL. In one or more embodiments, when the substrate SUB is provided as a glass substrate and/or a PI substrate, the semiconductor portion and the gate electrode may be included in the pixel circuit layer PCL. Each capacitor may include electrodes that are spaced (e.g., spaced apart) from each other. For example, each capacitor may include electrodes that are spaced (e.g., spaced apart) from each other on a plane defined by the first and second directions DR1 and DR2. For example, each capacitor may include electrodes that are (spaced (e.g., spaced apart) from each other in the third direction DR3 with an insulating layer therebetween.

The wires of the pixel circuit layer PCL may include signal lines connected to each of the first to third sub-pixels SP1, SP2, and SP3 for example, a gate line, a light emitting control line, and a data line. The wires may further include the wire connected to the first power voltage node VDDN of FIG. 2. In addition, the wires may further include the wire connected to the second power voltage node VSSN of FIG. 2.

The light emitting element layer LDL may include anode electrodes AE, a pixel defining layer PDL, a light emitting structure EMS, and a cathode electrode CE.

The anode electrodes AE may be disposed on the pixel circuit layer PCL. The anode electrodes AE may contact circuit elements of the pixel circuit layer PCL. The anode electrodes AE may include an opaque conductive material capable of reflecting light, but the present disclosure is not limited thereto.

The pixel defining layer PDL is disposed on the anode electrodes AE. The pixel defining layer PDL may include an opening OP exposing a portion of each of the anode electrodes AE. The opening OP of the pixel defining layer PDL may be defined as light emitting areas respectively corresponding to the first to third sub-pixels SP1 to SP3. Alternatively, it may be understood that light emitting areas respectively corresponding to the first to third sub-pixels SP1 to SP3 are defined according to the anode electrodes AE. In an area adjacent to the boundary of neighboring sub-pixels, the pixel defining layer PDL may include a separator causing a discontinuity to be formed within the light emitting structure EMS. In this case, it may be understood that light emitting areas respectively corresponding to the first to third sub-pixels SP1 to SP3 are defined according to the separators of the pixel defining layer PDL.

In one or more embodiments, the pixel defining layer PDL may include an inorganic material. In this case, the pixel defining layer PDL may include a plurality of stacked inorganic layers. For example, the pixel defining layer PDL may include a silicon oxide (SiOx) and/or a silicon nitride (SiNx). In one or more embodiments, the pixel defining layer PDL may include an organic material. However, the material of the pixel defining layer PDL is not limited thereto.

The light emitting structure EMS may be disposed on the anode electrodes AE exposed by the opening OP of the pixel defining layer PDL. The light emitting structure EMS may include a light emitting layer configured to generate light, an electron transport layer configured to transport electrons, and a hole transport layer configured to transport holes.

In one or more embodiments, the light emitting structure EMS may fill the opening OP of the pixel defining layer PDL, and may be disposed entirely on an upper portion of the pixel defining layer PDL. In other words, the light emitting structure EMS may extend across the first to third sub-pixels SP1 to SP3. In this case, at least some of the functional layers in the light emitting structure EMS may be disconnected or bent at the boundaries between the first to third sub-pixels SP1 to SP3. However, the present disclosure is not limited thereto. For example, portions of the light emitting structure EMS corresponding to the first to third sub-pixels SP1 to SP3 are separated from each other, and each of them may be disposed in the opening OP of the pixel defining layer PDL.

The cathode electrode CE may be disposed on the light emitting structure EMS. The cathode electrode CE may extend across the first to third sub-pixels SP1 to SP3. As such, the cathode electrode CE may be provided as a common electrode for the first to third sub-pixels SP1 to SP3.

The cathode electrode CE may be a thin metal layer with a thickness sufficient to transmit light emitted from the light emitting structure EMS. The cathode electrode CE may be made of a metallic material and/or a transparent conductive material to have a relatively thin thickness. In one or more embodiments, the cathode electrode CE may include at least one of various transparent conductive materials including an indium tin oxide, an indium zinc oxide, an indium tin zinc oxide, an aluminum zinc oxide, a gallium zinc oxide, a zinc tin oxide, and/or a gallium tin oxide. In one or more embodiments, the cathode electrode CE may include at least one of silver (Ag), magnesium (Mg), or a mixture thereof. However, the material of the cathode electrode CE is not limited thereto.

One of the anode electrodes AE, the portion of the light emitting structure EMS overlapping the anode electrodes AE, and the portion of the cathode electrode CE overlapping the light emitting structure EMS may be understood to configure one light emitting element LD (see FIG. 2). In other words, each of the light emitting elements of the first to third sub-pixels SP1 to SP3 may include one anode electrode AE, a portion of the light emitting structure EMS overlapping the anode electrode AE, and a portion of the cathode electrode CE overlapping light emitting structure EMS. In each of the first to third sub-pixels SP1 to SP3, holes injected from the anode electrode AE and electrons injected from the cathode electrode CE are transported into the light emitting layer of the light emitting structure EMS to form excitons, and when the excitons transition from the excited state to the ground state, light may be generated. The luminance of light may be determined depending on the amount of current flowing through the light emitting layer. Depending on the configuration of the light emitting layer, the wavelength range of the generated light may be determined.

The encapsulation layer TFE is disposed on the cathode electrode CE. The encapsulation layer TFE may cover the light emitting element layer LDL and/or the pixel circuit layer PCL. The encapsulation layer TFE may be configured to prevent oxygen and/or moisture from penetrating into the light emitting element layer LDL. In one or more embodiments, the encapsulation layer TFE may include a structure in which one or more inorganic films and one or more organic films are alternately stacked. For example, the inorganic film may include a silicon nitride, a silicon oxide, and/or a silicon oxynitride (SiOxNy). For example, the organic film may include an organic insulating material such as an acrylic resin, an epoxy resin, a phenol resin, a polyamide resin, a polyimide resin, an unsaturated polyesters resin, a polyphenylenethers resin, a polyphenylenesulfides resin, and/or a benzocyclobutene. However, the materials of the organic film and the inorganic film of the encapsulation layer TFE are not limited thereto.

The encapsulation layer TFE may further include a thin film containing an aluminum oxide (AlOx) to improve the encapsulation efficiency of the encapsulation layer TFE. The thin film containing an aluminum oxide may be disposed on the upper surface of the encapsulation layer TFE facing the optical functional layer OFL and/or the lower surface of the encapsulation layer TFE facing the light emitting element layer LDL.

The thin film containing the aluminum oxide may be formed through atomic layer deposition (ALD). However, the present disclosure is not limited thereto. The encapsulation layer TFE may further include a thin film made of at least one of various materials suitable for improving the encapsulation efficiency.

The optical functional layer OFL is disposed on the encapsulation layer TFE. The optical function layer OFL may include a color filter layer CFL and a lens array LA.

The color filter layer CFL is disposed between the encapsulation layer TFE and the lens array LA. The color filter layer CFL is configured to selectively output light in a wavelength range or color corresponding to each sub-pixel by filtering light emitted from the light emitting structure EMS. The color filter layer CFL includes color filters CF respectively corresponding to the first to third sub-pixels SP1 to SP3, and each of the color filters CF may pass light in a wavelength range corresponding to the sub-pixel. For example, a color filter corresponding to the first sub-pixel SP1 may pass red light, a color filter corresponding to the second sub-pixel SP2 may pass green light, and a color filter corresponding to the third sub-pixel SP3 may pass blue light. At least some of the color filters CF may be omitted according to light emitted from the light emitting structure EMS of each sub-pixel.

The lens array LA is disposed on the color filter layer CFL. The lens array LA may include lenses LSS respectively corresponding to the first to third sub-pixels SP1 to SP3. Each of the lenses LSS may improve light output efficiency by outputting light emitted from the light emitting structure EMS in an intended path. The lens array LA may have a relatively high refractive index. For example, the lens array LA may have a higher refractive index than the overcoat layer OC. In one or more embodiments, the lenses LSS may include an organic material. In one or more embodiments, the lenses LSS may include an acrylic material. However, the material of the lenses LSS is not limited thereto.

In one or more embodiments, compared to the opening OP of the pixel defining layer PDL, at least some of the color filters CF of the color filter layer CF and at least some of the lenses LSS of the lens array LA may be shifted in a direction parallel to a plane defined by the first and second directions DR1 and DR2. Specifically, in the center area of the display area DA, the center of the color filter CF and the center of the lens LSS may be aligned or overlapped with the center of the opening OP of the corresponding pixel defining layer PDL when viewed in the third direction DR3 (e.g., in a plan view). For example, in the central area of the display area DA, the opening OP of the pixel defining layer PDL may completely overlap the corresponding color filter of the color filter layer CFL and the corresponding lens LSS of the lens array LA. In an area of the display area DA adjacent to the non-display area NDA, the center of the color filter CF and the center of the lens LSS may be shifted in a planar direction from the center of the opening OP of the corresponding pixel defining layer PDL when viewed in the third direction DR3 (e.g., in a plan view). For example, in an area of the display area DA adjacent to the non-display area NDA, the opening OP of the pixel defining layer PDL may partially overlap the corresponding color filter CF of the color filter layer CFL and the corresponding lens LSS of the lens array LA. Accordingly, in the center of the display area DA, light emitted from the light emitting structure EMS may be efficiently outputted in the normal direction of the display surface. Light emitted from the light emitting structure EMS at the outside of the display area DA may be efficiently outputted in a direction inclined by a suitable angle (e.g., a predetermined angle) with respect to the normal direction of the display surface.

The overcoat layer OC may be disposed on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting lower layers thereof from foreign substances such as dust and/or moisture. For example, the overcoat layer OCL may include at least one of an inorganic insulating film or an organic insulating film. For example, the overcoat layer OC may include an epoxy resin, but the present disclosure is not limited thereto. The overcoat layer OC may have a lower refractive index than the lens array LA.

The cover window CW may be disposed on the overcoat layer OC. The cover window CW is configured to protect lower layers thereof. The cover window CW may have a higher refractive index than the overcoat layer OC. The cover window CW may include glass, but the present disclosure is not limited thereto. For example, the cover window CW may be an encapsulation glass configured to protect constituent elements disposed thereunder. In one or more embodiments, the cover window CW may be omitted.

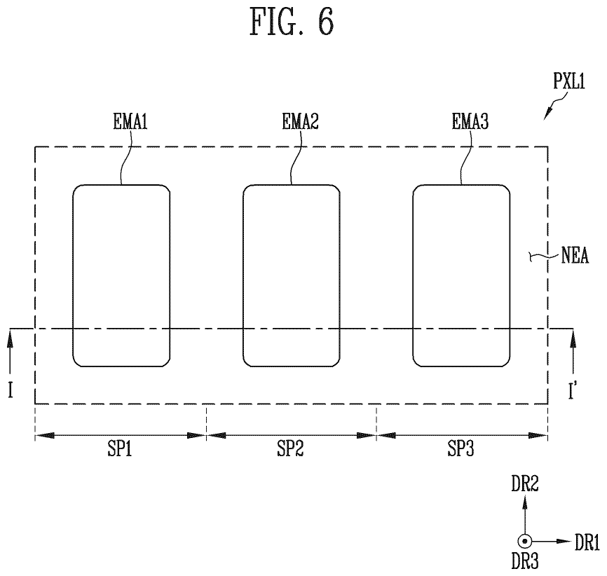

FIG. 6 illustrates a schematic top plan view of one of pixels of FIG. 5 according to one or more embodiments. For a clear and concise description in FIG. 6, the first pixel PXL1 from among the first and second pixels PXL1 and PXL2 of FIG. 5 is schematically illustrated. The remaining pixels may be configured similarly to the first pixel PXL1.

Referring to FIG. 5 and FIG. 6, a first pixel PXL1 may include the first to third sub-pixels SP1 to SP3 disposed along the first direction DR1.

The first sub-pixel SP1 may include a first light emitting area EMA1 and a non-light emitting area NEA around the first light emitting area EMA1. The second sub-pixel SP2 may include a second light emitting area EMA2 and the non-light emitting area NEA around the second light emitting area EMA2. The third sub-pixel SP3 may include a third light emitting area EMA3 and the non-light emitting area NEA around the third light emitting area EMA3.

The first light emitting area EMA1 may be an area in which light is emitted from a portion of the light emitting structure EMS (see FIG. 5) corresponding to the first sub-pixel SP1. The second light emitting area EMA2 may be an area in which light is emitted from a portion of the light emitting structure EMS corresponding to the second sub-pixel SP2. The third light emitting area EMA3 may be an area in which light is emitted from a portion of the light emitting structure EMS corresponding to the third sub-pixel SP3.

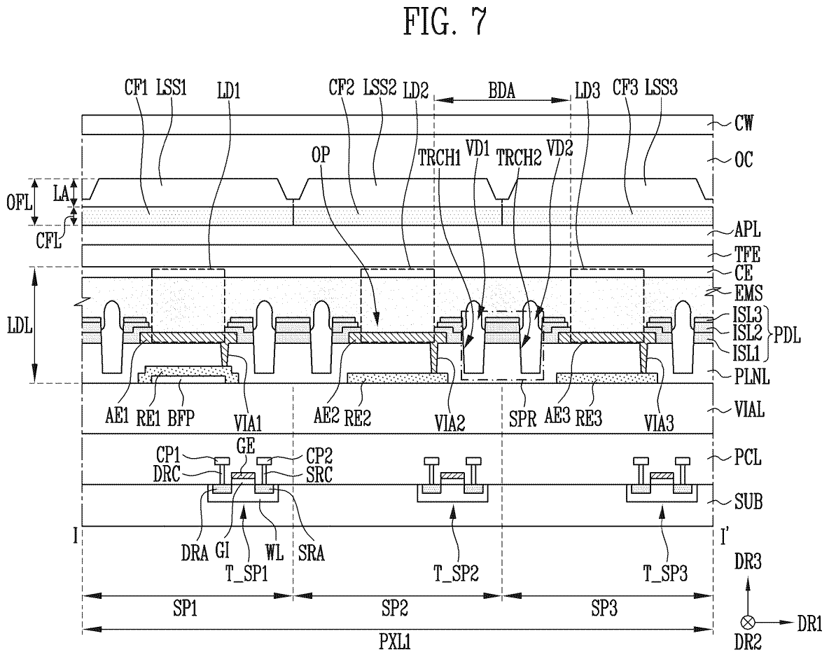

FIG. 7 illustrates a schematic cross-sectional view taken along the line I-I′ of FIG. 6 according to one or more embodiments.

Referring to FIG. 7, the substrate SUB and the pixel circuit layer PCL disposed on the substrate SUB are provided.

The substrate SUB may include a silicon wafer substrate formed using a semiconductor process. For example, the substrate SUB may include silicon, germanium, and/or silicon-germanium.

The pixel circuit layer PCL is disposed on the substrate SUB. The substrate SUB and the pixel circuit layer PCL may include circuit elements for each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (see FIG. 2) of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 6, for clear and concise description, one of the transistors of each sub-pixel is shown and the remaining circuit elements are omitted.

The transistor T_SP1 of the first sub-pixel SP1 may include a source area SRA, a drain area DRA, and a gate electrode GE.

The source area SRA and the drain area DRA may be disposed within the substrate SUB. A well WL formed through an ion injection process is disposed in the substrate SUB, and the source area SRA and the drain area DRA may be spaced (e.g., spaced apart) from each other within the well WL. The area between the source area SRA and the drain area DRA within the well WL may be defined as a channel area. The gate electrode GE overlaps the channel area between the source area SRA and the drain area DRA, and may be disposed on the pixel circuit layer PCL. The gate electrode GE may be separated from the well WL or the channel area by an insulating material such as a gate insulating layer GI. The gate electrode GE may include a conductive material.

A plurality of layers included in the pixel circuit layer PCL include insulating layers and conductive patterns disposed between the insulating layers, and the conductive patterns may include first and second conductive patterns CP1 and CP2. The first conductive pattern CP1 may be electrically connected to the drain area DRA through a drain connection portion DRC penetrating one or more insulating layers. The second conductive pattern CP2 may be electrically connected to the source area SRA through a source connection portion SRC penetrating one or more insulating layers.

As the gate electrode GE and the first and second conductive patterns CP1 and CP2 are connected to other circuit elements and/or wires, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1.

As described above, the substrate SUB and the pixel circuit layer PCL may include circuit elements for each of the first to third sub-pixels SP1 to SP3.

A via layer VIAL is disposed on the pixel circuit layer PCL. The via layer VIAL covers the pixel circuit layer PCL, and may have an overall flat surface. The via layer VIAL is configured to flatten steps on the pixel circuit layer PCL. The via layer VIAL may include a silicon oxide (SiOx), a silicon nitride (SiNx), and/or a silicon carbon nitride (SiCN), but the present disclosure is not limited thereto.

The light emitting element layer LDL is disposed on the via layer VIAL. The light emitting element layer LDL may include first to third reflective electrodes RE1 to RE3, a planarization layer PLNL, first to third anode electrodes AE1 to AE3, a pixel defining layer PDL, a light emitting structure EMS, and a cathode electrode CE.

The first to third reflective electrodes RE1 to RE3 are disposed in the first to third sub-pixels SP1 to SP3 on the via layer VIAL, respectively. Each of the first to third reflective electrodes RE1 to RE3 may contact a circuit element disposed on the pixel circuit layer PCL through a via penetrating the via layer VIAL.

The first to third reflective electrodes RE1 to RE3 may function as full mirrors that reflect light emitted from the light emitting structure EMS toward the display surface (or the cover window CW). The first to third reflective electrodes RE1 to RE3 may include metallic materials suitable for reflecting light. The first to third reflective electrodes RE1 to RE3 may include aluminum (Al), silver (Ag), magnesium (Mg), platinum (Pt), palladium (Pd), gold (Au), nickel (Ni), neodymium (Nd), iridium (Ir), chromium (Cr), titanium (Ti), and/or an alloy of two or more materials selected therefrom, but the present disclosure is not limited thereto.

In one or more embodiments, a connection electrode may be disposed below each of the first to third reflective electrodes RE1 to RE3. The connection electrode may improve the electrical connection characteristics between the corresponding reflective electrode and the circuit element of the pixel circuit layer PCL. The connection electrode may have a multi-layered structure. The multi-layered structure may include titanium (Ti), a titanium nitride (TiN), a tantalum nitride (TaN), and/or the like, but the present disclosure is not limited thereto. In one or more embodiments, a corresponding reflective electrode may be disposed between the multiple layers of the connecting electrode.

A buffer pattern BFP may be disposed below at least one of the first to third reflective electrodes RE1 to RE3. The buffer pattern BFP may include an inorganic material such as a silicon carbon nitride, but the present disclosure is not limited thereto. By disposing the buffer pattern BFP, the height of the corresponding reflective electrode in the third direction DR3 may be adjusted. For example, the buffer pattern BFP may be disposed between the first reflective electrode RE1 and the via layer VIAL to adjust the height of the first reflective electrode RE1.

The first to third reflective electrodes RE1 to RE3 may function as full mirrors, and the cathode electrode CE may function as a half mirror. For example, each of the first to third reflective electrodes RE1 to RE3 and the cathode electrode CE may provide a resonance structure in a corresponding sub-pixel. Light emitted from the light emitting layer of the light emitting structure EMS may be amplified by reciprocating between the reflective electrode RE (e.g., one or more of the reflective electrodes RE1 to RE3) and the cathode electrode CE, and the amplified light may be outputted through the cathode electrode CE. As such, the distance between each reflective electrode RE (e.g., one or more of the reflective electrodes RE1 to RE3) and the cathode electrode CE may be understood as the resonance distance for the light emitted from the light emitting layer of the corresponding light emitting structure EMS.

The first sub-pixel SP1 may have a shorter resonance distance than other sub-pixels due to the buffer pattern BFP (e.g., due to the distance between the first reflective electrode RE1 and the cathode electrode CE being shorter than the distances between the cathode electrode CE and each of the second and third reflective electrodes RE2 and RE3). The resonance distance adjusted in this way may allow light in a specific wavelength range (for example, red color) to be effectively and efficiently amplified. Accordingly, the first sub-pixel SP1 may effectively and efficiently output light in the corresponding wavelength range.

In FIG. 7, the buffer pattern BFP is shown to be provided in the first sub-pixel SP1 and not in the second and third sub-pixels SP2 and SP3, but the present disclosure is not limited thereto. The buffer pattern may be also provided in at least one of the second sub-pixel SP2 or the third sub-pixel SP3, so that the resonance distance of at least one of the second sub-pixel SP2 or the third sub-pixel SP3 may be adjusted. For example, the first to third sub-pixels SP1 to SP3 may correspond to red, green, and blue, respectively, the distance between the first reflective electrode RE1 and the cathode electrode CE may be shorter than the distance between the second reflective electrode RE2 and the cathode electrode CE, and the distance between the second reflective electrode RE2 and the cathode electrode CE may be shorter than the distance between the third reflective electrode RE3 and the cathode electrode CE.

To planarize the steps between the first to third reflective electrodes RE1 to RE3, the planarization layer PLNL may be disposed on the via layer VIAL and the first to third reflective electrodes RE1 to RE3. The planarization layer PLNL may entirely cover the first to third reflective electrodes RE1 to RE3 and the via layer VIAL, and may have a flat surface. In one or more embodiments, the planarization layer PLNL may be omitted.

The first to third anode electrodes AE1 to AE3 respectively overlapping the first to third reflective electrodes RE1 to RE3 are disposed on the planarization layer PLNL. The first to third anode electrodes AE1 to AE3 may have shapes similar to the first to third light emitting areas EMA1 to EMA3 of FIG. 6 when viewed in the third direction DR3 (e.g., in a plan view). The first to third anode electrodes AE1 to AE3 are respectively connected to the first to third reflective electrodes RE1 to RE3. The first anode electrode AE1 may be connected to the first reflective electrode RE1 through the first via VIA1 penetrating the planarization layer PLNL. The second anode electrode AE2 may be connected to the second reflective electrode RE2 through the second via VIA2 penetrating the planarization layer PLNL. The third anode electrode AE3 may be connected to the third reflective electrode RE3 through the third via VIA3 penetrating the planarization layer PLNL.

In one or more embodiments, the first to third anode electrodes AE1 to AE3 may include at least one of transparent conductive materials such as an indium tin oxide (ITO), an indium zinc oxide (IZO), a zinc oxide (ZnOx), an indium gallium zinc oxide (IGZO), or an indium tin zinc oxide (ITZO). However, the materials of the first to third anode electrodes AE1 to AE3 are not limited thereto. For example, the first to third anode electrodes AE1 to AE3 may include a titanium nitride.

The pixel defining layer PDL is disposed on some of the first to third anode electrodes AE1 to AE3 and the planarization layer PLNL. The pixel defining layer PDL has an opening OP exposing a portion of each of the first to third anode electrodes AE1 to AE3. An area overlapping the pixel defining layer PDL may be understood as a boundary area BDA between adjacent sub-pixels.

In one or more embodiments, the pixel defining layer PDL may include a plurality of inorganic insulating layers. Each of the plurality of inorganic insulating layers may include at least one of a silicon oxide (SiOx) or a silicon nitride (SiNx). For example, the pixel defining layer PDL may include a first inorganic insulating layer ISL1, a second inorganic insulating layer ISL2, and a third inorganic insulating layer ISL3 sequentially stacked. The first to third inorganic insulating layers ISL1 to ISL3 may include a silicon nitride, a silicon oxide, and/or a silicon oxynitride, but the present disclosure is not limited thereto. The first to third inorganic insulating layers ISL1 to ISL3 may have a step-shaped cross-section in an area adjacent to the opening OP.

The pixel defining layer PDL may include a separator SPR in the boundary area BDA between adjacent sub-pixels. In other words, the separator SPR may be provided in each of the boundary areas between the sub-pixels SP in FIG. 4.

The separator SPR may cause a discontinuity to be formed within the light emitting structure EMS in the boundary area BDA. For example, the light emitting structure EMS may be disconnected and/or bent in the boundary area BDA by the separator SPR. Accordingly, the first to third light emitting areas EMA1 to EMA3 of FIG. 6 respectively corresponding to the first to third sub-pixels SP1 to SP3 may be defined according to the separator SPR of the pixel defining layer PDL.

The separator SPR may be provided in or on the pixel defining layer PDL. The pixel defining layer PDL may include one or more trenches TRCH1 and TRCH2 as the separator SPR in the boundary area BDA. In one or more embodiments, as shown in FIG. 7, one or more trenches TRCH1 and TRCH2 may penetrate the pixel defining layer PDL and partially penetrate the planarization layer PLNL. In one or more embodiments, one or more trenches TRCH1 and TRCH2 may penetrate the pixel defining layer PDL and the planarization layer PLNL, and may partially penetrate the via layer VIAL. In one or more embodiments, one or more trenches TRCH1 and TRCH2 at least partially penetrate the planarization layer PLNL and/or the via layer VIAL, and a portion of the pixel defining layer PDL may be disposed in one or more trenches TRCH1 and TRCH2.

FIG. 7 illustrates that two trenches TRCH1 and TRCH2 are provided in the boundary region BDA. However, the present disclosure is not limited thereto. For example, the pixel defining film PDL may include one trench in the boundary area BDA. Alternatively, the pixel defining layer PDL may include three or more trenches in the boundary area BDA.

Due to the first and second trenches TRCH1 and TRCH2, discontinuous portions such as the first void VD1 and the second void VD2 may be formed in the light emitting structure EMS in the boundary area BDA. Some of the plurality of layers stacked in the light emitting structure EMS may be disconnected and/or bent by the first and second voids VD1 and VD2. For example, at least one charge generation layer and at least one hole injection layer included in the light emitting structure EMS may be disconnected in the first and second voids VD1 and VD2. As described above, due to the first and second trenches TRCH1 and TRCH2, the portions of the light emitting structure EMS included in the first to third sub-pixels SP1 to SP3 may be at least partially separated.

Depending on the shapes of the first and second trenches TRCH1 and TRCH2, the discontinuities formed in the light emitting structure EMS may vary.

In one or more embodiments, the light emitting structure EMS may be formed through processes such as vacuum deposition and/or inkjet printing. In this case, the same materials as the light emitting structure EMS may be disposed on the bottom surfaces of the first and second trenches TRCH1 and TRCH2 adjacent to the via layer VIAL.

The pixel defining layer PDL may include an additional separator so that the light emitting structure EMS further includes a discontinuous portion adjacent to the boundary area BDA. In one or more embodiments, the uppermost third inorganic insulating layer ISL3 from among the first to third inorganic insulating layers ISL1 to ISL3 of the pixel defining layer PDL may have a wider width than the second inorganic insulating layer ISL2 disposed directly below the third inorganic insulating layer. For example, the pixel defining layer PDL may have a cross-section of a “T” or “I” shape in the boundary area BDA. Depending on the shape of the pixel defining layer PDL, a plurality of layers included in the light emitting structure EMS may be at least partially disconnected and/or bent in the boundary area BDA or in an area adjacent to the boundary area BDA.

The light emitting structure EMS may be disposed on the anode electrodes AE exposed by the opening OP of the pixel defining layer PDL. The light emitting structure EMS may fill the opening OP of the pixel defining layer PDL, and may be disposed entirely across the first to third sub-pixels SP1 to SP3. As described above, the light emitting structure EMS may be at least partially disconnected and/or bent in the boundary area BDA by the separator SPR (e.g., TRCH1, TRCH2). Accordingly, when the display panel DP operates, the current leaking from each of the first to third sub-pixels SP1 to SP3 to the neighboring sub-pixel through the layers included in the light-emitting structure EMS may decrease. Accordingly, the first to third light emitting elements LD1 to LD3 may operate with relatively high reliability.

The cathode electrode CE may be disposed on the light emitting structure EMS. The cathode electrode CE may be provided commonly for the first to third sub-pixels SP1 to SP3. The cathode electrode CE may function as a half mirror that partially transmits and partially reflects light emitted from the light emitting structure EMS.

The first anode electrode AE1, the portion of the light emitting structure EMS overlapping the first anode electrode AE1, and the portion of the cathode electrode CE overlapping the first anode electrode AE1 may configure the first light emitting element LD1. The second anode electrode AE2, the portion of the light emitting structure EMS overlapping the second anode electrode AE2, and the portion of the cathode electrode CE overlapping the second anode electrode AE2 may configure the second light emitting element LD2. The third anode electrode AE3, the portion of the light emitting structure EMS overlapping the third anode electrode AE3, and the portion of the cathode electrode CE overlapping the third anode electrode AE3 may configure the third light emitting element LD3.

The encapsulation layer TFE is disposed on the cathode electrode CE. The encapsulation layer TFE may prevent oxygen and/or moisture from penetrating into the light emitting element layer LDL.

The optical functional layer OFL is disposed on the encapsulation layer TFE. In one or more embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting the lower layers including the encapsulation layer TFE.

The optical functional layer OFL may include a color filter layer CFL and a lens array LA. The color filter layer CFL may include first to third color filters CF1 to CF3 respectively corresponding to the first to third sub-pixels SP1 to SP3. The first to third color filters CF1 to CF3 may pass light in different wavelength ranges. For example, the first to third color filters CF1 to CF3 may pass red, green, and blue colored light, respectively.

In one or more embodiments, the first to third color filters CF1 to CF3 may partially overlap in the boundary area BDA. In one or more other embodiments, the first to third color filters CF1 to CF3 may be spaced (e.g., spaced apart) from each other, and a black matrix may be provided between the first to third color filters CF1 to CF3.

The lens array LA is disposed on the color filter layer CFL. The lens array LA may include first to third lenses LSS1 to LSS3 respectively corresponding to the first to third sub-pixels SP1 to SP3. The first to third lenses LSS1 to LSS3 may improve light output efficiency by outputting the light emitted from the first to third light emitting elements LD1 to LD3, respectively, along an intended path.

The overcoat layer OC may be disposed on the lens array LA. The overcoat layer OC is configured to protect its lower layers from foreign substances such as dust, moisture, and/or the like. The cover window CW may be disposed on the overcoat layer OC.

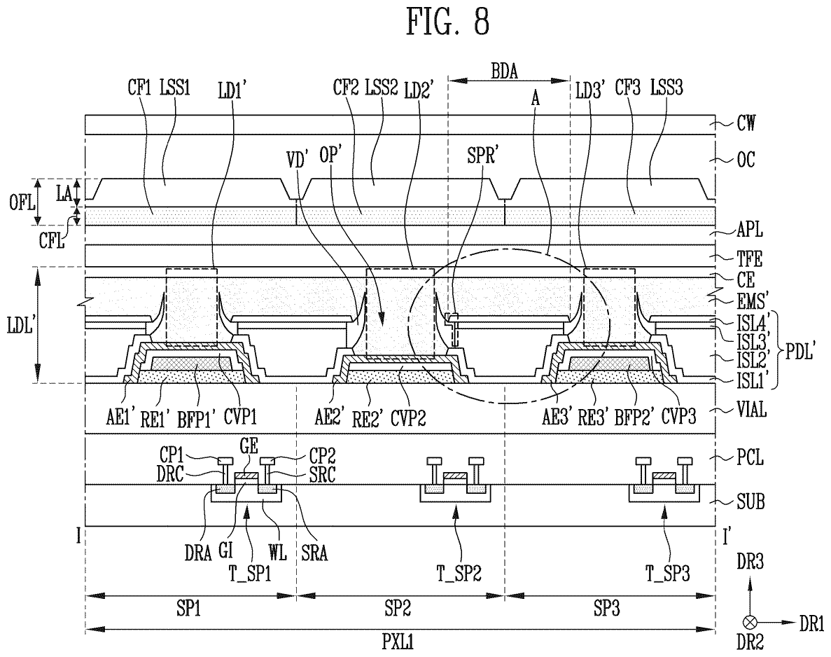

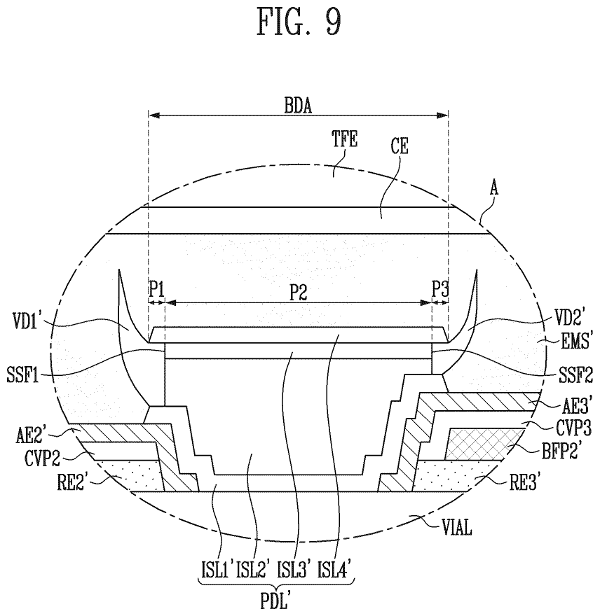

FIG. 8 illustrates a schematic cross-sectional view taken along the line I-I′ of FIG. 6 according to one or more other embodiments. FIG. 9 illustrates a schematic enlarged view of an area “A” of FIG. 8.

Referring to FIG. 8, a pixel circuit layer PCL and a via layer VIAL are disposed on a substrate SUB. The substrate SUB, the pixel circuit layer PCL, and the via layer VIAL of FIG. 8 are configured similarly to the substrate SUB, the pixel circuit layer PCL, and the via layer VIAL of FIG. 7. Hereinafter, redundant descriptions thereof will be omitted.

A light emitting element layer LDL′ is disposed on the via layer VIAL. The light emitting element layer LDL′ may include first to third reflective electrodes RE1′ to RE3′, first and second buffer patterns BFP1′ and BFP2′, first to third cover patterns CVP1 to CVP3, first to third anode electrodes AE1′ to AE3′, a pixel defining layer PDL′, a light emitting structure EMS′, and a cathode electrode CE.

The first to third reflective electrodes RE1′ to RE3′ are disposed in the first to third sub-pixels SP1 to SP3 on the via layer VIAL, respectively. Each of the first to third reflective electrodes RE1′ to RE3′ may contact a circuit element disposed on the pixel circuit layer PCL through a via penetrating the via layer VIAL.

The first to third reflective electrodes RE1′ to RE3′ are configured to reflect light emitted from the light emitting structure EMS′ toward the display surface (or the cover window CW). The first to third reflective electrodes RE1′ to RE3′ may include metallic materials suitable for reflecting light. The first to third reflective electrodes RE1′ to RE3′ may include aluminum (Al), silver (Ag), magnesium (Mg), platinum (Pt), palladium (Pd), gold (Au), nickel (Ni), neodymium (Nd), iridium (Ir), chromium (Cr), titanium (Ti), and/or an alloy of two or more materials selected therefrom, but the present disclosure is not limited thereto.

In one or more embodiments, a connection electrode may be further provided between each of the first to third reflective electrodes RE1′ to RE3′ and the via layer VIAL. The connection electrode may improve the electrical connection characteristics between the corresponding reflective electrode and the circuit element of the pixel circuit layer PCL. The connection electrode may have a multi-layered structure. The multi-layered structure may include titanium (Ti), aluminum (Al), a titanium nitride (TiN), a tantalum nitride (TaN), and/or the like, but the present disclosure is not limited thereto. In one or more embodiments, a corresponding reflective electrode may be disposed between the multiple layers of the connecting electrode.

A buffer pattern may be disposed on at least one of the first to third reflective electrodes RE1′ to RE3′. In one or more embodiments, the first and second buffer patterns BFP1′ and BFP2′ may be disposed on the first and third reflective electrodes RE1′ and RE3′, respectively. Heights of the first and third anode electrodes AE1′ and AE3′ in the third direction DR3 may be adjusted by the first and second buffer patterns BFP1′ and BFP2′. The first and second buffer patterns BFP1′ and BFP2′ may include an inorganic material such as a silicon oxide (SiOx) and/or a silicon nitride (SiNx), but the present disclosure is not limited thereto.

The first to third cover patterns CVP1 to CVP3 may be disposed on the first to third reflective electrodes RE1′ to RE3′, respectively. In the first sub-pixel SP1, the first cover pattern CVP1 is disposed on the first reflective electrode RE1′ and the first buffer pattern BFP1′. In the second sub-pixel SP2, the second cover pattern CVP2 is disposed on the second reflective electrode RE2′. In the third sub-pixel SP3, the third cover pattern CVP3 is disposed on the third reflective electrode RE3′ and the second buffer pattern BFP2′. The first to third cover patterns CVP1 to CVP3 may be formed after the formation of the first and second buffer patterns BFP1′ and BFP2′ during the manufacturing process. The first to third cover patterns CVP1 to CVP3 may include the same material as the first and second buffer patterns BFP1′ and BFP2′. For example, the first to third cover patterns CVP1 to CVP3 may include inorganic materials such as a silicon oxide (SiOx) and/or a silicon nitride (SiNx), but the present disclosure is not limited thereto.

The first to third anode electrodes AE1′ to AE3′ are disposed on the first to third cover patterns CVP1 to CVP3, respectively. In one or more embodiments, the first anode electrode AE1′ may cover the first cover pattern CVP1, the first buffer pattern BFP1′, and the first reflective electrode RE1′. The second anode electrode AE2′ may cover the second cover pattern CVP2 and the second reflective electrode RE2′. The third anode electrode AE3′ may cover the third cover pattern CVP3, the second buffer pattern BFP2′, and the third reflective electrode RE3′.

The first to third anode electrodes AE1′ to AE3′ may be electrically connected to the first to third reflective electrodes RE1′ to RE3′, respectively. For example, each anode electrode may be connected to an end (or edge) of the corresponding reflective electrode. However, the present disclosure is not limited thereto. In order to improve the electrical connection characteristics between the anode electrode and the reflective electrode, the anode electrode may be connected to the reflective electrode in various ways.

In one or more embodiments, the first to third anode electrodes AE1′ to AE3′ may include at least one of transparent conductive materials such as an indium tin oxide (ITO), an indium zinc oxide (IZO), a zinc oxide (ZnOx), an indium gallium zinc oxide (IGZO), and/or an indium tin zinc oxide (ITZO). However, the materials of the first to third anode electrodes AE1′ to AE3′ are not limited thereto. For example, the first to third anode electrodes AE1′ to AE3′ may include a titanium nitride.

The first to third anode electrodes AE1′ to AE3′ may have shapes similar to the first to third light emitting areas EMA1 to EMA3 of FIG. 6 when viewed in the third direction DR3 (e.g., in a plan view).

The first to third anode electrodes AE1′ to AE3′ and the cathode electrode CE may partially reflect incident light. Light emitted from the light emitting layer of the light emitting structure EMS′ may be amplified by reciprocating between the anode electrode AE (e.g., AE1′ to AE3′) and the cathode electrode CE, and may be outputted through the cathode electrode CE. For example, each anode electrode AE (e.g., AE1′ to AE3′) and the cathode electrode CE may provide a resonance structure in a corresponding sub-pixel. In this case, the distance between each anode electrode and the cathode electrode CE may be understood as the resonance distance for the light emitted from the light emitting layer of the corresponding light emitting structure EMS.

The first to third sub-pixels SP1 to SP3 may correspond to red, green, and blue, respectively. In this case, heights of the first and third anode electrodes AE1′ and AE3′ in the third direction DR3 may be higher than the second anode electrode AE2′ by the first and second buffer patterns BFP1′ and BFP2′. Accordingly, the first and third sub-pixels SP1 and SP3 may have a shorter resonance distance than the second sub-pixel SP2 due to the first and second buffer patterns BFP1′ and BFP2′. In this way, the resonance distance of each sub-pixel may be adjusted so that light in the wavelength range of the corresponding color is effectively and efficiently amplified.

In FIG. 8, the first and second buffer patterns BFP1′ and BFP2′ are shown to be respectively disposed below the first and third anode electrodes AE1′ and AE3′, but the present disclosure is not limited thereto. For example, one of the first or second buffer patterns BFP1′ or BFP2′ may be omitted. As another example, both the first and second buffer patterns BFP1′ and BFP2′ may be omitted. In this case, the resonance distances between respective anode electrodes AE (e.g., one or more of the first to third anode electrodes AE1′ to AE3′) and the cathode electrode CE may be the same. As another example, a buffer pattern may be disposed below each of the first to third anode electrodes AE1′ to AE3′. In this case, the buffer patterns disposed below respective anode electrodes may have different thicknesses, and accordingly, the resonance distances between respective anode electrodes AE (e.g., one or more of the first to third anode electrodes AE1′ to AE3′) and the cathode electrode CE may be different from each other. As described above, by providing the buffer pattern below at least one of the first to third anode electrodes AE1′ to AE3′ for adjusting the height of the anode electrode, the resonance distance in each sub-pixel may be optimized. Herein the height of the anode electrode refers to a distance between a top surface of the anode electrode (e.g., the respective ones of the first to third anode electrodes AE1′ to AE3′) and the substrate SUB.

The pixel defining layer PDL′ is disposed on portions of the first to third anode electrodes AE1′ to AE3′ and on the via layer VIAL. The pixel defining layer PDL′ has an opening OP′ exposing a portion of each of the first to third anode electrodes AE1′ to AE3′. An area overlapping the pixel defining layer PDL′ may be understood as the boundary area BDA between adjacent sub-pixels.

The pixel defining layer PDL′ may include a plurality of inorganic insulating layers sequentially stacked. Each of the plurality of inorganic insulating layers may include at least one of a silicon oxide (SiOx) or a silicon nitride (SiNx). However, the present disclosure is not limited thereto. For example, the pixel defining layer PDL′ may include an organic insulating layer.

In one or more embodiments, the pixel defining layer PDL′ may include first to fourth inorganic insulating layers ISL1′ to ISL4′. The first inorganic insulating layer ISL1′ may cover portions of the first to third anode electrodes AE1′ to AE3′ and the via layer VIAL. The second inorganic insulating layer ISL2′ is disposed on the first inorganic insulating layer ISL1′, the third inorganic insulating layer ISL3′ is disposed on the second inorganic insulating layer ISL2′, and the fourth inorganic insulating layer ISL4′ is disposed on the third inorganic insulating layer ISL3′. The first and third inorganic insulating layers ISL1′ and ISL3′ may include a silicon nitride (SiNx), and the second and fourth inorganic insulating layers ISL2′ and ISL4′ may include a silicon oxide (SiOx), but the present disclosure is not limited thereto. In one or more embodiments, the first inorganic insulating layer ISL1′ may be omitted.

The pixel defining layer PDL′ may include a separator SPR′ in the boundary area BDA between adjacent sub-pixels. The separator SPR′ may cause a discontinuous part such as a void VD′ to be formed in the light emitting structure EMS′. Due to the discontinuous portion, at least some of the plurality of layers included in the light emitting structure EMS′ may be disconnected and/or bent.

The fourth inorganic insulating layer ISL4′ may have a wider width than the second and third inorganic insulating layers ISL2′ and ISL3′. In this case, side surfaces of the second to fourth inorganic insulating layers ISL2′ to ISL4′ adjacent to the opening OP′ may be provided as the separator SPR′.

Referring to FIG. 9 together with FIG. 8, the fourth inorganic insulating layer ISL4′ may include first to third portions P1 to P3. The second portion P2 may completely overlap the second and third inorganic insulating layers ISL2′ and ISL3′. The first portion P1 protrudes from the second portion P2 in a direction opposite to the first direction DR1. The third portion P3 protrudes from the second portion P2 in the first direction DR1. As such, a width of the fourth inorganic insulating layer ISL4′ may be wider than those of the second and third inorganic insulating layers ISL2′ and ISL3′. For example, during the manufacturing process, the second and third inorganic insulating layers ISL2′ and ISL3′ may be undercut so as not to include portions overlapping the first and third portions P1 and P3. For example, each of the first and third portions P1 and P3 of the fourth inorganic insulating layer ISL4′ may have a shape of eaves on the second and third inorganic insulating layers ISL2′ and ISL3′.

In the boundary area BDA, the second and third inorganic insulating layers ISL2′ and ISL3′ may have the same width. However, the present disclosure is not limited thereto, and the second and third inorganic insulating layers ISL2′ and ISL3′ may have different widths. For example, the second inorganic insulating layer ISL2′ may have a wider width than the third inorganic insulating layer ISL3′. As another example, the third inorganic insulating layer ISL3′ may have a wider width than the second inorganic insulating layer ISL2′.

In the second sub-pixel SP2, the first portion P1 of the fourth inorganic insulating layer ISL4′ and the first side surface SSF1 of the second and third inorganic insulating layers ISL2′ and ISL3′ may be provided as one separator SPR′. Accordingly, the first void VD1′ adjacent to the first portion P1 of the fourth inorganic insulating layer ISL4′ may be formed in the light emitting structure EMS′. In the third sub-pixel SP3, the third portion P3 of the fourth inorganic insulating layer ISL4′ and the second side surface SSF2 of the second and third inorganic insulating layers ISL2′ and ISL3′ may be provided as another separator SPR′. Accordingly, the second void VD2′ adjacent to the third portion P3 of the fourth inorganic insulating layer ISL4′ may be formed in the light emitting structure EMS′.

Some of the plurality of layers stacked in the light emitting structure EMS may be disconnected and/or bent by the first and second voids VD1′ and VD2′. For example, at least one charge generation layer and at least one hole injection layer included in the light emitting structure EMS may be disconnected by the first and second voids VD1′ and VD2′. As described above, due to the separator SPR′, the portions of the light emitting structure EMS′ included in the first to third sub-pixels SP1 to SP3 may be at least partially separated from each other.

The pixel defining layer PDL′ may include an additional separator so that the light emitting structure EMS′ further includes a discontinuous portion in the boundary area BDA. In one or more embodiments, the pixel defining layer PDL′ may include one or more trenches as a separator in the boundary area BDA. The trenches may penetrate one or more of the first to fourth inorganic insulating layers ISL1′ to ISL4′. Due to the trenches, some of the plurality of layers stacked in the light emitting structure EMS′, for example, at least one charge generation layer and at least one hole injection layer, may be disconnected and/or bent. In one or more embodiments, the light emitting structure EMS′ may have a structure in which three light emitting portions each including a light emitting layer are stacked, and two charge generation layers may be disposed between the three light emitting portions. In one or more embodiments, the pixel defining layer PDL′ may include one or more trenches in the boundary area BDA.

Referring again to FIG. 8, the light emitting structure EMS′ may be disposed on the anode electrodes AE′ (e.g., one or more of the first to third anode electrodes AE1′ to AE3′) exposed by the opening OP′ of the pixel defining layer PDL′. The light emitting structure EMS′ may fill the opening OP′ of the pixel defining layer PDL′, and may be disposed entirely across the first to third sub-pixels SP1 to SP3. As described above, the light emitting structure EMS′ may be disconnected and/or bent in the boundary area BDA or an area adjacent to the boundary area BDA by the separator SPR′. Accordingly, during the operation of the display panel DP, the current flowing out from each of the first to third sub-pixels SP1 to SP3 through the layers included in the light emitting structure EMS′ may decrease. Accordingly, the first to third light emitting elements LD1′ to LD3′ may operate with relatively high reliability.

In one or more embodiments, the light emitting structure EMS′ may include two light emitting portions sequentially stacked, and each of the light emitting portions may include a light emitting layer configured to generate light according to an applied current. In one or more other embodiments, the light emitting structure EMS′ may include three light emitting portions sequentially stacked, and each of the light emitting portions may include a light emitting layer configured to generate light according to an applied current. In these embodiments, a charge generation layer may be disposed between the light emitting portions.

In one or more embodiments, the light emitting structure EMS′ may be formed through processes such as vacuum deposition or inkjet printing.

The cathode electrode CE may be disposed on the light emitting structure EMS′. The cathode electrode CE may be provided commonly for the first to third sub-pixels SP1 to SP3.

The first anode electrode AE1′, the portion of the light emitting structure EMS′ overlapping the first anode electrode AE1′, and the portion of the cathode electrode CE overlapping the first anode electrode AE1′ may configure the first light emitting element LD1′. The second anode electrode AE2′, the portion of the light emitting structure EMS′ overlapping the second anode electrode AE2′, and the portion of the cathode electrode CE overlapping the second anode electrode AE2′ may configure the second light emitting element LD2′. The third anode electrode AE3′, the portion of the light emitting structure EMS′ overlapping the third anode electrode AE3′, and the portion of the cathode electrode CE overlapping the third anode electrode AE3′ may configure the third light emitting element LD3′.

The encapsulation layer TFE is disposed on the cathode electrode CE. The encapsulation layer TFE may prevent oxygen and/or moisture from penetrating into the light emitting element layer LDL′.

An adhesive layer APL, an optical functional layer OFL, an overcoat layer OC, and a cover window CW are disposed on the encapsulation layer TFE. The adhesive layer APL, the optical functional layer OFL, the overcoat layer OC, and the cover window CW are configured similarly to the adhesive layer APL, the optical functional layer OFL, the overcoat layer OC, and the cover window CW of FIG. 7, respectively. Duplicate descriptions of these are omitted.

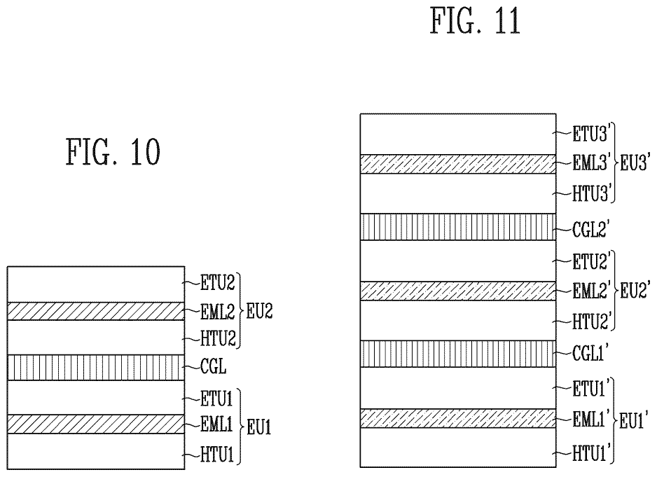

FIG. 10 illustrates a cross-sectional view of a portion of a light emitting structure included in one of first to third light emitting elements of FIG. 7 or FIG. 8 according to one or more embodiments.

Referring to FIG. 10, the light emitting structure may have a tandem structure in which first and second light emitting portions EU1 and EU2 are stacked. The light emitting structure may be configured to be substantially the same in each of the first to third light emitting elements LD1 to LD3 of FIG. 7.

Each of the first and second light emitting portions EU1 and EU2 may include at least one light emitting layer that generates light according to a current applied thereto. The first light emitting portion EU1 may include a first light emitting layer EML1, a first electron transport portion ETU1, and a first hole transport portion HTU1. The first light emitting layer EML1 may be disposed between the first electron transport portion ETU1 and the first hole transport portion HTU1. The second light emitting portion EU2 may include a second light emitting layer EML2, a second electron transport portion ETU2, and a second hole transport portion HTU2. The second light emitting layer EML2 may be disposed between the second electron transport portion ETU2 and the second hole transport portion HTU2.

Each of the first and second hole transport portions HTU1 and HTU2 may include at least one of a hole injection layer and/or a hole transport layer, and may further include a hole buffer layer, an electron blocking layer, and/or the like as needed. The first and second hole transport portions HTU1 and HTU2 may have the same configuration or different configurations.

Each of the first and second electron transport portions ETU1 and ETU2 may include at least one of an electron injection layer or an electron transport layer, and may further include an electron buffer layer and a hole blocking layer as needed. The first and second electron transport portions ETU1 and ETU2 may have the same configuration or different configurations.

A connection layer, which may be provided in the form of a charge generation layer CGL, may be disposed between the first light emitting portion EU1 and the second light emitting portion EU2 to connect them to each other. In one or more embodiments, the charge generation layer CGL may have a stacked structure of a p dopant layer and an n dopant layer. For example, the p dopant layer may include a p-type dopant such as HAT-CN, TCNQ, and NDP-9, and the n dopant layer may include an alkali metal, an alkaline earth metal, a lanthanide-based metal, and/or a combination thereof. However, the present disclosure is not limited thereto.

In one or more embodiments, the first light emitting layer EML1 and the second light emitting layer EML2 may generate light of different colors. The light emitted from each of the first light emitting layer EML1 and the second light emitting layer EML2 may be mixed to be recognized as white light. For example, the first light emitting layer EML1 may generate blue-colored light, and the second light emitting layer EML2 may generate yellow-colored light. In one or more embodiments, the second light-emitting layer EML2 may include a structure in which a first sub-light-emitting layer configured to generate red-colored light and a second sub-light-emitting layer configured to generate green-colored light are stacked. The red-colored light and the green-colored light may be mixed to provide yellow-colored light. In this case, an intermediate layer configured to perform a function of transporting holes and/or preventing transport of electrons may be further disposed between the first and second sub-light emitting layers.

In one or more other embodiments, the first light emitting layer EML1 and the second light emitting layer EML2 may generate light of the same color.

The light emitting structure may be formed through a vacuum deposition method, an inkjet printing method, and/or the like, but the present disclosure is not limited thereto.

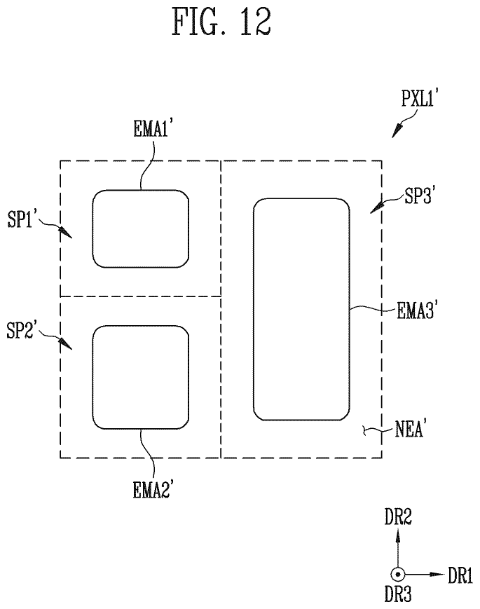

FIG. 11 illustrates a cross-sectional view of a portion of a light emitting structure included in one of first to third light emitting elements of FIG. 7 or FIG. 8 according to one or more other embodiments.

Referring to FIG. 11, the light emitting structure may have a tandem structure in which first to third light emitting portions EU1′ to EU3′ are stacked. The light emitting structure may be configured to be substantially the same in each of the first to third light emitting elements LD1 to LD3 of FIG. 7.

Each of the first to third light emitting portions EU1′ to EU3′ may include a light emitting layer that generates light according to a current applied thereto. The first light emitting portion EU1′ may include a first light emitting layer EML1′, a first electron transport portion ETU1′, and a first hole transport portion HTU1′. The first light emitting layer EML1′ may be disposed between the first electron transport portion ETU1′ and the first hole transport portion HTU1′. The second light emitting portion EU2′ may include a second light emitting layer EML2′, a second electron transport portion ETU2′, and a second hole transport portion HTU2′. The second light emitting layer EML2′ may be disposed between the second electron transport portion ETU2′ and the second hole transport portion HTU2′. The third light emitting portion EU3′ may include a third light emitting layer EML3′, a third electron transport portion ETU3′, and a third hole transport portion HTU3′. The third light emitting layer EML3′ may be disposed between the third electron transport portion ETU3′ and the third hole transport portion HTU3′.

Each of the first to third hole transport portions HTU1′ to HTU3′ may include at least one of a hole injection layer or a hole transport layer, and may further include a hole buffer layer, an electron blocking layer, and/or the like as needed. The first to third hole transport portions HTU1′ to HTU3′ may have the same configuration or different configurations.

Each of the first to third electron transport portions ETU1′ to ETU3′ may include at least one of an electron injection layer and an electron transport layer, and may further include an electron buffer layer and a hole blocking layer as needed. The first to third electron transport portions ETU1′ to ETU3′ may have the same configuration or different configurations.

A first charge generation layer CGL1′ is disposed between the first light emitting portion EU1′ and the second light emitting portion EU2′. A second charge generation layer CGL2′ is disposed between the second light emitting portion EU2′ and the third light emitting portion EU3′.

In one or more embodiments, the first to third light emitting layers EML1′ to EML3′ may generate light of different colors. Light emitted from each of the first to third light emitting layers EML1′ to EML3′ may be mixed to be viewed as white light. For example, the first light emitting layer EML1′ may generate light of a blue color, the second light emitting layer EML2′ may generate light of a green color, and the third light emitting layer EML3′ may generate light of a red color.

In one or more other embodiments, two or more of the first to third light emitting layers EML1′ to EML3′ may generate light of the same color.

Unlike shown in FIG. 10 and FIG. 11, the light emitting structure of FIG. 7 or FIG. 8 may include one light emitting portion in each of the first to third light emitting elements LD1 to LD3. In this case, the light emitting portions respectively included in the first to third light emitting elements LD1 to LD3 may be configured to emit light of different colors. For example, the light emitting portion of the first light emitting element LD1 may emit red-colored light, the light emitting portion of the second light emitting element LD2 may emit green-colored light, and the light emitting portion of the third light emitting element LD3 may emit blue-colored light. In this case, the light emitting portions of the first to third sub-pixels SP1 to SP3 are separated from each other, and each of them may be disposed within the opening (see OP in FIG. 7 and OP′ in FIG. 8) of the pixel defining layer (see PDL in FIG. 7 and PDL′ in FIG. 8). In this case, at least some of the color filters CF1 to CF3 may be omitted.

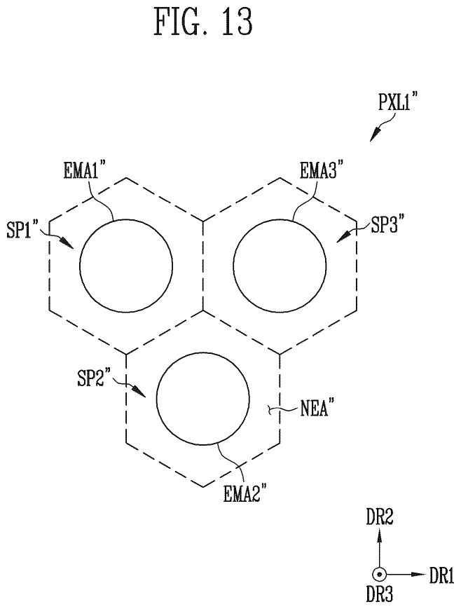

FIG. 12 illustrates a schematic top plan view of one of pixels of FIG. 5 according to one or more embodiments.

Referring to FIG. 12, a first pixel PXL1′ may include first to third sub-pixels SP1′ to SP3′.

The first sub-pixel SP1′ may include a first light emitting area EMA1′ and a non-light emitting area NEA′ around the first light emitting area EMA1′. The second sub-pixel SP2′ may include a second light emitting area EMA2′ and a non-light emitting area NEA′ around the second light emitting area EMA2′. The third sub-pixel SP3′ may include a third light emitting area EMA3′ and a non-light emitting area NEA′ around the third light emitting area EMA3′.

The first sub-pixel SP1′ and the second sub-pixel SP2′ may be disposed in (e.g., arranged along) the second direction DR2. The third sub-pixel SP3′ may be disposed in the first direction DR1 with respect to each of the first and second sub-pixels SP1′ and SP2′.

The second sub-pixel SP2′ may have a larger area than the first sub-pixel SP1′, and the third sub-pixel SP3′ may have a larger area than the second sub-pixel SP2′. Accordingly, the second light emitting area EMA2′ may have a larger area than the first light emitting area EMA1′, and the third light emitting area EMA3′ may have a larger area than the second light emitting area EMA2′. However, the present disclosure is not limited thereto. For example, the first and second sub-pixels SP1′ and SP2′ may have substantially the same area, and the third sub-pixel SP3′ may have a larger area than each of the first and second sub-pixels SP1′ and SP2′. As such, the areas of the first to third sub-pixels SP1′ to SP3′ may be variously changed depending on embodiments.

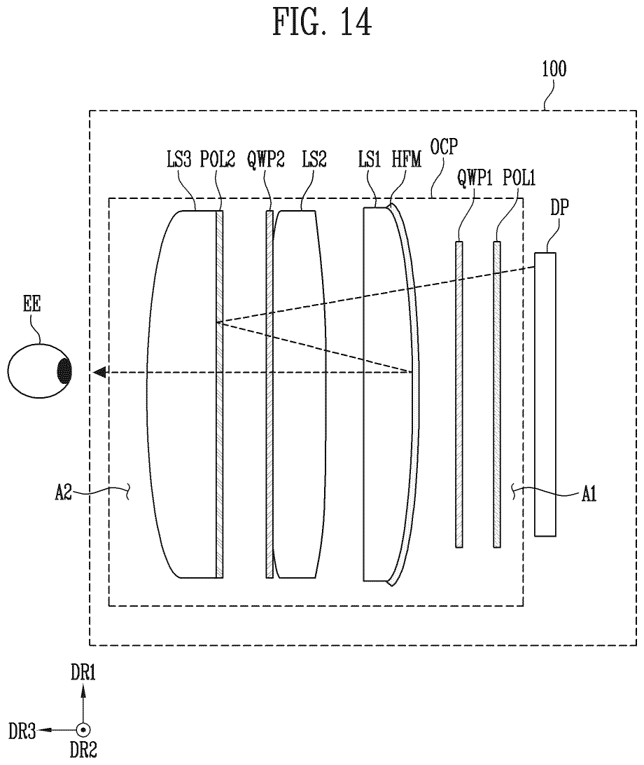

FIG. 13 illustrates a schematic top plan view of one of pixels of FIG. 5 according to one or more embodiments.

Referring to FIG. 13, the first sub-pixel SP1″ may include a first light emitting area EMA1″ and a non-light emitting area NEA″ around the first light emitting area EMA1″. The second sub-pixel SP2″ may include a second light emitting area EMA2″ and a non-light emitting area NEA″ around the second light emitting area EMA2″. The third sub-pixel SP3″ may include a third light emitting area EMA3″ and a non-light emitting area NEA″ around the third light emitting area EMA3″.

The first to third sub-pixels SP1″ to SP3″ may have polygonal shapes when viewed in the third direction DR3 (e.g., in a plan view). For example, the shapes of the first to third sub-pixels SP1″ to SP3″ may have hexagonal shapes as shown in FIG. 13.

The first to third light emitting areas EMA1″ to EMA3″ may have circular shapes when viewed in the third direction DR3 (e.g., in a plan view). However, the present disclosure is not limited thereto. For example, each of the first to third light emitting areas EMA1″ to EMA3″ may have a polygonal shape.

The first and third sub-pixels SP1″ and SP3″ may be disposed in (e.g., arranged along) the first direction DR1. The second sub-pixel SP2″ may be disposed in a direction (or a diagonal direction) inclined by an acute angle with respect to the second direction DR2 with respect to the first sub-pixel SP1″.

The dispositions of the sub-pixels illustrated in FIGS. 6, 12, and 13 are merely examples, and the present disclosure is not limited thereto. Each pixel may include two or more sub-pixels, the sub-pixels may be variously disposed, each of the sub-pixels may have various shapes, and each of its light emitting areas may also have various shapes.

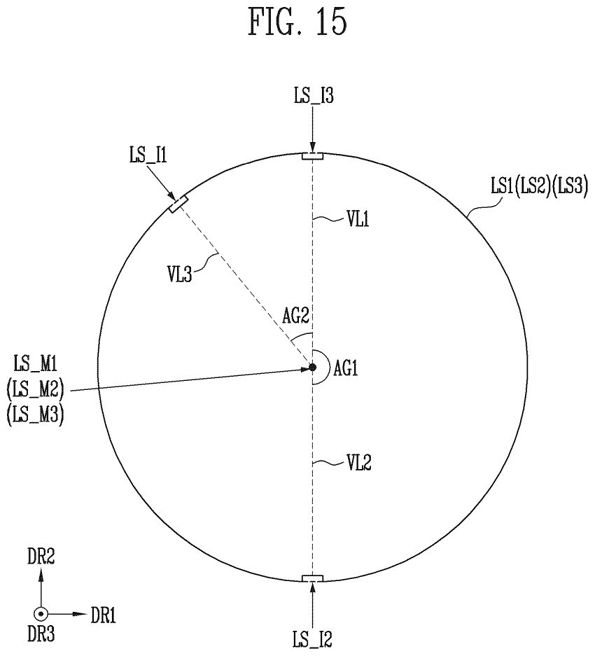

FIG. 14 illustrates a schematic cross-sectional view of the display device according to one or more embodiments. Referring to FIG. 14, the display device 100 may further include a lens assembly OCP. The lens assembly OCP may be disposed on the display panel DP (e.g., a surface from which light is emitted from the display panel DP) and may transmit light provided from the display panel DP. The lens assembly OCP may guide light provided from the display panel DP.

The lens assembly OCP may be a pancake lens. A pancake lens is a lens using folded optics, and may refer to a lens structure in which a plurality of lenses and polarizing elements are overlapped. The lens assembly OCP may guide light and widen the area in which a user may observe an image (eye box). Accordingly, the lens assembly OCP may provide virtual reality or augmented reality to the user.

The lens assembly OCP may include an incident side A1 that may be disposed adjacent to the display panel DP in the third direction DR3, and an exit side A2 that is opposite to the incident side A1. For example, the incident side A1 may be disposed closer to the display panel DP than the exit side A2, and the exit side A2 may be disposed closer to the eye EE of the user using the display device 100 than the incident side A1. For example, the incident side A1 may be a side on which light emitted from the display panel DP is incident, and the exit side A2 may be a side from which light incident on the incident side A1 is exited.

The lens assembly OCP may include a first lens LS1 disposed adjacent to the incident side A1, a second lens LS2 disposed on the first lens LS1, and a third lens LS3 disposed on the second lens LS2 and disposed adjacent to the exit side A2. For example, the first lens LS1 may be disposed closer to the incident side A1 than the third lens LS3, and the third lens LS3 may be disposed closer to the exit side A2 than the first lens LS1. For example, the first lens LS1 may be disposed farther from the user's eye EE than the third lens LS3, and the third lens LS3 may be disposed closer to the user's eyes EE than the first lens LS1.

The lens assembly OCP may include a first polarization layer POL1, a first quarter wave plate QWP1, a partially reflective mirror layer HFM, a second quarter wave plate QWP2, and a second polarization layer POL2. In one or more embodiments, the lens assembly OCP may have a structure in which the first polarization layer POL1, the first quarter wave plate QWP1, the partially reflective mirror layer HFM, the first lens LS1, the second lens LS2, the second quarter wave plate QWP2, the second polarization layer POL2, and the third lens LS3 are sequentially disposed.

For example, the first polarization layer POL1 may be disposed on the display panel DP, the first quarter wave plate QWP1 may be disposed on the first polarizing layer POL1, the partially reflective mirror layer HFM may be disposed on the first quarter wave plate QWP1, the first lens LS1 may be disposed on the partially reflective mirror layer HFM, the second lens LS2 may be disposed on the first lens LS1, the second quarter wave plate QWP2 may be disposed on the second lens LS2, the second polarizing layer POL2 may be disposed on the second quarter wave plate QWP2, and the third lens LS3 may be disposed on the second polarizing layer POL2. However, the present disclosure is not limited thereto.

The first polarization layer POL1 may have a transmission axis (or a passing axis) aligned along one direction (e.g., the first direction DR1 or the second direction DR2). The first polarization layer POL1 may be a linear polarization layer. The first polarization layer POL1 may linearly polarize light emitted from the display panel DP. For example, the first polarization layer POL1 may transmit only light that vibrates along the transmission axis of the first polarization layer POL1 and may not transmit the remaining light. Accordingly, as the light emitted from the display panel DP passes through the first polarization layer POL1, it may be aligned with the transmission axis of the first polarization layer POL1 and may be linearly polarized.

The first quarter wave plate QWP1 may have an optical axis aligned at 45 degrees with respect to the transmission axes of the first polarization layer POL1. The first quarter wave plate QWP1 may change linearly polarized light into circularly polarized light or change circularly polarized light into linearly polarized light by providing a phase difference of λ/4. For example, the first quarter wave plate QWP1 may left-circularly polarize light that passed through the first quarter wave plate QWP1 after passing through the first polarizing layer POL1. For example, when light that passes through the first polarizing layer POL1 has linearly polarized light of 0°, and when it passes through the first quarter wave plate QWP1, it may become left-circularly polarized (LCP) light. In one or more embodiments, the first quarter wave plate QWP1 may right-circularly polarize the light passing through the first quarter waveplate QWP1 after passing through the first polarizing layer POL1. However, for convenience, the present disclosure will be described with reference to an embodiment in which the light passing through first quarter wave plate QWP1 is left-circularly polarized.

The partially reflective mirror layer HFM may include a metallic mirror coating, or other mirror coating, such as a dielectric multilayer coating that is 50% transparent and 50% reflective, on a surface thereof. The partially reflective mirror layer HFM may transmit light incident to a first surface (for example, a surface facing the display panel DP) of the partially reflective mirror layer HFM, and reflect light incident on a second surface (for example, a surface opposite to the surface facing the display panel DP) of the partially reflective mirror layer HFM.

The polarization state of light that passes through the partially reflective mirror layer HFM may remain unchanged. For example, the polarization state of the light passing through the first quarter wave plate QWP1 and then passing through the partially reflective mirror layer HFM may be same as the polarization state of light passed through the first quarter wavelength plate QWP1 before passing through the partially reflecting mirror layer HFM.

The second quarter wave plate QWP2 may have an optical axis aligned at −45 degrees with respect to the transmission axes of the first polarization layer POL1 (for example, an optical axis symmetrical to the optical axis of the first quarter wave plate QWP1). The second quarter wave plate QWP2 may change linearly polarized light into circularly polarized light or change circularly polarized light into linearly polarized light by providing a phase difference of λ/4. For example, the second quarter wave plate QWP2 may right-circularly polarize light that passed through the second quarter wave plate QWP2. For example, when light that passes through the second quarter wave plate QWP2 may convert left-circularly polarized light that passed through the partially reflective mirror layer HFM into linearly polarized light.

The second polarizing layer POL2 may have a transmission axis (or a passing axis) perpendicularly aligned with the transmission axis of the first polarizing layer POL1. The second polarizing layer POL2 may be a reflective polarizing layer. For example, the second polarizing layer POL2 may transmit only light that vibrates along the transmission axis of the second polarizing layers POL2, and reflect the remaining light.

The light reflected by the second polarizing layer POL2 passes through the second quarter wave plate QWP2 again and may be reflected by the partially reflective mirror layer HFM. The light reflected by the partially reflective mirror layer HFM passes through the second quarter wave plate QWP2 again, and then incidents to the second polarizing layer POL2 and passes through the second polarizing layers POL2. As such, the path of light emitted from the display panel DP may be folded as it passes through the lens assembly OCP, and the lens assembly OCP may provide a higher sense of immersion to the user.

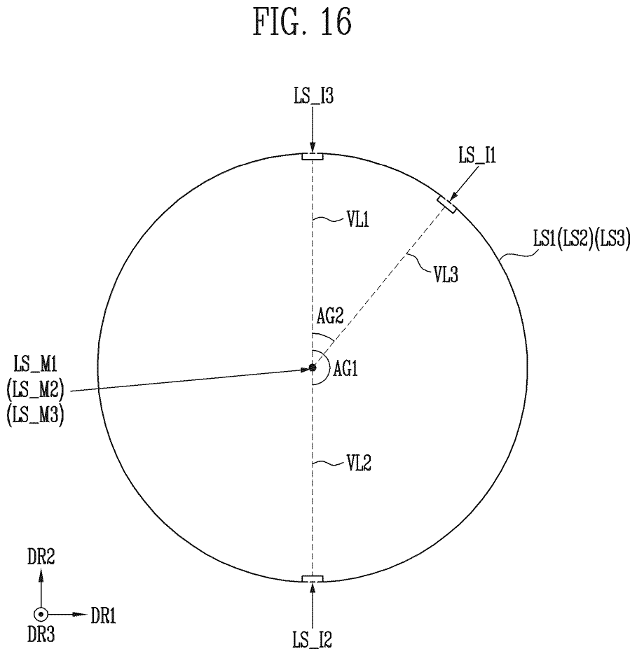

FIGS. 15 and 16 illustrate schematic plan views showing the placement of a first lens, a second lens, and a third lens according to one or more embodiments.

Referring to FIG. 15, the first lens LS1 may include a first lens material injection part LS_I1. The second lens LS2 may include a second lens material injection part LS_I2. The third lens LS3 may include a third lens material injection part LS_I3.

Each of the first lens LS1, the second lens LS2, and the third lens LS3 according to the present disclosure may be formed by being injected by an injection molding process. For example, a material for forming each of the first lens LS1, the second lens LS2, and the third lens LS3 may be injected into a mold (e.g., a mold for manufacturing a lens) through a screw, and the material injected may harden to form each of the first, second, and third lenses LS1 and LS3.

Each of the first lens material injection part LS_I1, the second lens material injection part LS_I2, and the third lens material injection part LS_I3 may correspond to an injection part in which a material for forming each of the first lens LS1, the second lens LS2, and the third lenses LS3 is injected when the injection molding process proceeds. For example, in the injection molding process, the injection part into which the material forming each of the first lens LS1, the second lens LS2, and the third lens LS3 is injected, and each of the first lens material injection part LS_I1, the second lens material injection part LS_I2, and the third lens material injection part LS_I3 may be disposed at the same position. For example, in the injection molding process, the injection part into which the material forming each of the first lens LS1, the second lens LS2, and the third lens LS3 is injected, and each of the first lens material injection part LS_I1, the second lens material injection part LS_I2, and the third lens material injection part LS_I3 may be connected to each other. For example, a position at which the first lens material injection part LS_I1, the second lens material injection part LS_I2, and the third lens material injection part LS_I3 are formed in the injection molding process may overlap a position of an injection part at which the material forming each of the first lens LS1, the second lens LS2, and the third lenses LS3 is injected in the injection molding process.

In each of the first lens material injection part LS_I1, the second lens material injection part LS_I2, and the third lens material injection part LS_I3, a surface of each of the first lenses LS1, the second lenses LS2, and the third lenses LS3 may form a step. For example, in a region that overlaps (or is connected to) the first lens material injection part LS_I1, a surface of the first lens LS1 may be recessed (or indented) toward a center LS_M1 of the first lens LS1 to form a step. For example, in a region overlapping (or connected) with the second lens material injection part LS_I2, a surface of the second lens LS2 may be recessed (or indented) toward a center LS_M2 of the second lens LS2 to form a step. For example, in a region overlapping with (or connected to) the third lens material injection part LS_I3, a surface of the third lens LS3 may be recessed (or indented) toward a center LS_M3 of the third lens LS3 to form a step.

When viewed in a plan view, the first lens material injection part LS_I1, the second lens material injection part LS_I2, and the third lens material injection part LS_I3 may be disposed at different positions from each other.

The position of the first lens material injection part LS_I1 of the lens assembly OCP according to one or more embodiments may be determined according to the position of the third lens material injection part LS_I3. For example, in a plan view, the first lens material injection part LS_I1 may be spaced from the third lens material injection part LS_I3 along a periphery (e.g., a circumference) of the first lens LS1 or the third lens LS3 (e.g., as shown in FIG. 15, in a plan view, the first lens material injection part LS_I1 may be spaced from the third lens material injection part LS_I3 at an angle (e.g., AG2) formed between a third virtual line VL3 and a first virtual line VL1). For example, in a plan view, the first lens material injection part LS_I1 may be disposed at the lower left of the third lens material injection part LS_I3 based on the position where the third lens material injection part LS_I3 is disposed (e.g., the first lens material injection part LS_I1 may be located left of the third lens material injection part LS_I3 along a periphery (e.g., a circumference) of the first lens LS1 or the third lens LS3, as shown in FIG. 15). For example, in a plan view, the first lens material injection part LS_I1 may be disposed along a direction crossing between a direction opposite to the first direction DR1 and a direction opposite to a second direction DR2. However, the present disclosure is not limited thereto.

According to one or more embodiments, referring to FIG. 16, in a plan view, the first lens material injection part LS_I1 may be located at a lower right of the third lens material injection part LS_I3 (e.g., the first lens material injection part LS_I1 may be located right of the third lens material injection part LS_I3 along a periphery (e.g., a circumference) of the first lens LS1 or the third lens LS3, as shown in FIG. 16). For example, in a plan view, the first lens material injection part LS_I1 may be disposed along a direction crossing between the first direction DR1 and a direction opposite to the second direction DR2.

The position of the second lens material injection part LS_I2 of the lens assembly OCP according to one or more embodiments may be determined according to the position of the third lens material injection part LS_I3. For example, in a plan view, the second lens material injection part LS_I2 may be disposed on the opposite side of the third lens material injection part LS_I3. For example, a surface of the third lens LS3 on which the third lens material injection part LS_I3 is defined and a surface of the second lens LS2 on which the second lens material injection part LS_I2 is defined may face in opposite directions. For example, based on the center LS_M3 of the third lens LS3, the third lens material injection part LS_I3 may be located above the center LS_ M3 of the third lens LS3, and based on the center LS_M2 of the second lens LS2, the second lens material injection part LS_I2 may be located below the center LS_M2 of the second lens LS2 (or the center LS_ M3 of the third lens LS3).

When viewed in a plan view, a first virtual line VL1 passing through the center of the third lens material injection part LS_I3 and the center LS_M3 of the third lens LS3 (e.g., the first virtual lines VL1 vertically passing through the third lens material injection part LS_I3) may form a first angle AG1 with a second virtual line VL2 passing through the center LS_M2 of the second lens LS2 and the center of the second lens material injection part LS_I2 (e.g., the second virtual line VL2 vertically passing through the second lens material injection part LS_I2). According to one or more embodiments, the first angle AG1 may be 170° to 180°. For example, the first angle AG1 may be greater than or equal to 170° and less than or equal to 180°. Hereinafter, the expression “A to B” in the numerical range may be defined as “A or more and B or less”. According to one or more embodiments, the first angle AG1 may be 180°.

In FIGS. 15 and 16, the center of the third lens material injection part LS_I3 is shown to be disposed at a point located at the uppermost side in the second direction DR2 from among the points forming the edge of the third lens LS3 in a plan view. However, the present disclosure is not limited thereto.

Hereinafter, for clarity and concise description, a point located on the uppermost side in the second direction DR2 from among the points forming the edge of the lens is defined as a “0° position of the lens”. And in order to describe the positions of the second lens material injection part LS_I2 and the first lens material injection part LS_I1 as compared with the third lens material injection part LS_I3, it is assumed that the center of the third lens material injection part LS_I3 is disposed at a position rotated by 0° to 5° in the clockwise direction or a position rotated in the counterclockwise direction by 0° to the 5° with respect to the 0° position of the third lens LS3.

Hereinafter, “a position at which a configuration of the lens is rotated by an angle from the original position” may be defined as “a position at a point where a virtual line forming the angle with a virtual line connecting from the original position to the center of the lens meets the lens”.

According to one or more embodiments, the center of the second lens material injection part LS_I2 may be disposed at a point located at the lowermost side in the second direction DR2 from among the points forming the edge of the second lens LS2 in a plan view. Hereinafter, from among the points forming the edge of the lens, a point located at the lowermost side in the second direction DR2 is defined as the “180° position of the lens”. According to one or more embodiments, the center of the second lens material injection part LS_I2 may be disposed at a position rotated by 0° to 5° in the clockwise direction or a position rotated in the counterclockwise direction by 0° to 5° with respect to the 180° position of the second lens LS2.

According to one or more embodiments, the first angle AG1 may be 170° to 190° with respect to a clockwise direction (e.g., when the angle is defined in clockwise). For example, when the center of the third lens material injection part LS_I3 is disposed at a position rotated by 5° counterclockwise with respect to the 0° position of the third lens LS3, and the center of the second lens material injection part LS_I2 is disposed at a position rotated by 5° clockwise with respect to the 180° position of the second lens LS2, the first angle AG1 may be 190° with respect to the clockwise direction.

According to one or more embodiments, the center of the first lens material injection part LS_I1 may be disposed at a position rotated by 40° to 50° in the clockwise direction or a position rotated in the counterclockwise direction by 40° to 50° with respect to the 0° position of the first lens LS1. According to one or more embodiments, the center of the first lens material injection part LS_I1 may be disposed at a position rotated by 45° clockwise or counterclockwise with respect to the 0° position of the first lens LS1.

When viewed in a plan view, the first virtual line VL1 passing through the center of the third lens material injection part LS_I3 and the center of the third lens LS3 may form a second angle AG2 with a third virtual line VL3 passing through a center of the first lens material injection part LS_I1 and a center LS_M1 of the first lens LS1 (e.g., the third imaginary line VL3 vertically passing through the first lens material injection part LS_I1) injection part. According to one or more embodiments, the second angle AG2 may be 35° to 55°. According to one or more embodiments, the second angle AG2 may be 45°. For example, referring to FIG. 15, the center of the first lens material injection part LS_I1 may be disposed at a position rotated by 315° in the clockwise direction with respect to the 0° position of the first lens LS1, and the second angle AG2 may be 315° with respect to the clockwise direction. For example, referring to FIG. 16, the center of the first lens material injection part LS_I1 may be disposed at a position rotated by 45° in the clockwise direction with respect to the 0° position of the first lens LS1, and the second angle AG2 may be 45° with respect to the clockwise direction.

When viewed in a plan view, the center of the first lens material injection part LS_I1 may not be disposed on a virtual line connecting the center of the second lens material injection part LS_I2 and the center of the third lens material injection part LS_I3. For example, in a plan view, the center of the first lens material injection part LS_I1 may not overlap a virtual line connecting the center of the second lens material injection part LS_I2 and the center of the third lens material injection part LS_I3.

Experimentally, because the materials of the lens disposed adjacent to the first lens material injection part LS_I1, the second lens material injection part LS_I2, and the third lens material injection part LS_I3 are subjected to high pressure in the injection molding process, if the first lens material injection part LS_I1, the second lens material injection part LS_ I2, and the third lens material injection part LS_I3 are disposed at the same position in a plan view, the birefringence occurrence frequency may be increased. In comparison, according to the lens assembly OCP according to one or more embodiments of the present disclosure, as the first lens material injection part LS_I1, the second lens material injection part LS_I2, and the third lens material injection part LS_I3 are disposed to form the first angle AG1 of 170° to 180° and the second angle AG2 of 35° to 55°, whether birefringence of the lens assembly OCP occurs (or the birefringence occurrence frequency) may be controlled.

When the first lens material injection part LS_I1, the second lens material injection part LS_I2, and the third lens material injection part LS_I3 are not disposed to form the first angle AG1 of 170° to 180° and the second angle AG2 of 35° to 55°, the conditions of the injection molding process (e.g., temperature of the mold, temperature at which the material for forming the lens is cooled, and/or the like) for forming each of the first lens LS1, the second lens LS2, and the third lenses LS3 may be controlled to control whether birefringence occurs (or the birefringence occurrence frequency) in the lens assembly OCP. However, because the lens assembly OCP has a structure in which a plurality of lenses LS1, LS2, and LS3 are stacked, even if the occurrence (or frequency) of birefringence of each of the first lens LS1, the second lens LS2, and the third lens LS3 is controlled in the injection process, the occurrence (or the frequency) of the birefringence of the lens assembly OCP may not be controlled as intended. According to the lens assembly OCP according to one or more embodiments of the present disclosure, the positions of the first lens material injection part LS_I1, the second lens material injection partLS_I2, and the third lens material injection part LS_I3 are adjusted, so that whether birefringence occurs (or the birefringence occurrence frequency) in the lens assembly OCP may be easily controlled, and the occurrence (or the frequency) of the birefringence in the lens assembly OCP may be controlled as intended.

Accordingly, the risk of birefringence occurring in the lens assembly OCP may be reduced, and the display quality of the display device 100 according to one or more embodiments of the present disclosure may be improved. For example, the risk of birefringence occurring in the lenses LS1, LS2, LS3 of the lens assembly OCP may be reduced, and the risk of a ghost image phenomenon (e.g., a phenomenon in which an image appears to overlap) occurring may be reduced. According to one or more embodiments, when the first angle AG1 is 180°, and the second angle AG2 is 45°, the display quality of the display device 100 according to one or more embodiments of the present disclosure may be further improved.

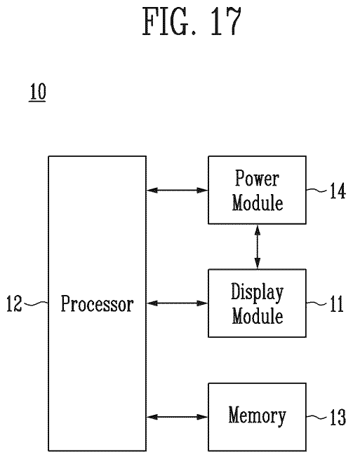

FIG. 17 illustrates a schematic block diagram of an electronic device according to one or more embodiments. Referring to FIG. 17, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device 100 according to one or more embodiments as described above. In addition, in terms of functionality, some of the individual modules included in one module may be included in the display device 100 and others may be provided separately from the display device 100. For example, the display module 11 is included in the display device, whereas the processor 12, the memory 13, and the power module 14 are not included in the display device and are instead provided separately in the electronic device 10.

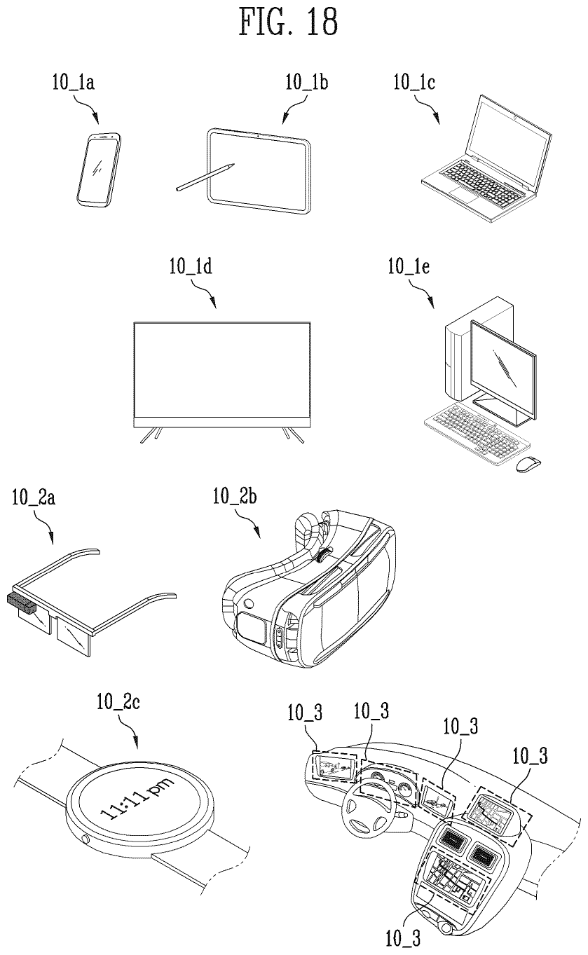

FIG. 18 illustrates a schematic diagram of an electronic device according to one or more embodiments.

Referring to FIG. 18, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

While the present disclosure has been shown and described with reference to certain embodiments thereof, it will be understood by those skilled in the art that various changes in forms and details may be made therein without departing from the spirit and scope of the present disclosure as defined by the appended claims and their equivalents.

Therefore, the technical scope of the present disclosure may be determined by the technical scope of the accompanying claims and their equivalents.

What is claimed is:

1. A lens assembly having an incident side on which light is incident and an exit side opposite to the incident side, the lens assembly comprising:
a first lens adjacent to the incident side;
a second lens on the first lens; and
a third lens on the second lens and adjacent to the exit side,
wherein the first lens has a first lens material injection part,
wherein the second lens has a second lens material injection part,
wherein the third lens has a third lens material injection part, and
wherein the first lens material injection part, the second lens material injection part, and the third lens material injection part are at different positions from each other in a plan view.

2. The lens assembly of claim 1,
wherein a first virtual line passing through a center of the third lens material injection part and a center of the third lens, and a second virtual line passing through a center of the second lens and a center of the second lens form a first angle, and
wherein the first angle is 170° to 180°.

3. The lens assembly of claim 2,
wherein the first virtual line and a third virtual line passing through a center of the first lens material injection part and a center of the first lens form a second angle,
wherein the second angle is 35° to 55°.

4. The lens assembly of claim 3,
wherein the first angle is 180°, and
wherein the second angle is 45°.

5. The lens assembly of claim 3,
wherein the second angle is 45° or 315° with respect to a clockwise direction.

6. The lens assembly of claim 5,
wherein the first virtual line vertically passes through the third lens material injection part,
wherein the second virtual line vertically passes through the second lens material injection part, and
wherein the third virtual line vertically passes through the first lens material injection part.

7. The lens assembly of claim 1,
wherein the second lens material injection part is on an opposite side of the third lens material injection part, in a plan view.

8. The lens assembly of claim 7,
wherein the first lens material injection part is spaced from the third lens material injection part along a periphery of the first lens or the third lens, in a plan view.

9. The lens assembly of claim 8,
wherein the first lens material injection part is at left or right of the third lens material injection part along a periphery of the first lens or the third lens, in a plan view.

10. The lens assembly of claim 9,
wherein each of the first lens, the second lens, and the third lens is formed by an injection molding process,
wherein the first lens material injection part corresponds to an injection part into which a material forming the first lens is injected in the injection process,
wherein the second lens material injection part corresponds to an injection part into which a material forming the second lens is injected in the injection process, and
wherein the third lens material injection part corresponds to an injection part into which a material forming the third lens is injected in the injection process.

11. The lens assembly of claim 1, further comprising:
a first polarization layer between the incident side and the first lens;
a first quarter wave plate on the first polarization layer;
a partially reflective mirror layer on the first quarter wave plate;
a second quarter wave plate between the second lens and the third lens; and
a second polarization layer between the second quarter wave plate and the third lens.

12. A display device comprising:
a display panel; and
a lens assembly on the display panel and having an incident side on which light provided from the display panel is incident and an exit side opposite to the incident side,
wherein the lens assembly comprises:
a first lens adjacent to the incident side;
a second lens on the first lens; and
a third lens on the second lens and adjacent to the exit side,
wherein the first lens has a first lens material injection part,
wherein the second lens has a second lens material injection part,
wherein the third lens has a third lens material injection part, and
wherein the first lens material injection part, the second lens material injection part, and the third lens material injection part are at different positions from each other in a plan view.

13. The display device of claim 12,
wherein a first virtual line passing through a center of the third lens material injection part and a center of the third lens, and a second virtual line passing through a center of the second lens and a center of the second lens form a first angle,
wherein the first virtual line and a third virtual line passing through a center of the first lens material injection part and a center of the first lens form a second angle,
wherein the first angle is 170° to 180°, and
wherein the second angle is 35° to 55°.

14. The display device of claim 13,
wherein the first angle is 180°,
wherein the second angle is 45° or 315° with respect to a clockwise direction,
wherein the first virtual line vertically passes through the third lens material injection part,
wherein the second virtual line vertically passes through the second lens material injection part, and
wherein the third virtual line vertically passes through the first lens material injection part.

15. The display device of claim 12,
wherein the second lens material injection part is on an opposite side of the third lens material injection part, in a plan view, and
wherein the first lens material injection part is spaced from the third lens material injection part along a periphery of the first lens or the third lens, in a plan view.

16. The display device of claim 15,
wherein each of the first lens, the second lens, and the third lens is formed by an injection molding process,
wherein the first lens material injection part corresponds to an injection part into which a material forming the first lens is injected in the injection process,
wherein the second lens material injection part corresponds to an injection part into which a material forming the second lens is injected in the injection process, and
wherein the third lens material injection part corresponds to an injection part into which a material forming the third lens is injected in the injection process.

17. The display device of claim 12,
wherein the lens assembly further comprises:
a first polarization layer between the incident side and the first lens;
a first quarter wave plate on the first polarization layer;
a partially reflective mirror layer on the first quarter wave plate;
a second quarter wave plate between the second lens and the third lens; and
a second polarization layer between the second quarter wave plate and the third lens.

18. An electronic device comprising:
a display device; and a processor,
wherein the display device comprises:
a display panel; and
a lens assembly on the display panel and having an incident side on which light provided from the display panel is incident and an exit side opposite to the incident side,
wherein the lens assembly comprises:
a first lens adjacent to the incident side;
a second lens on the first lens; and
a third lens on the second lens and adjacent to the exit side,
wherein the first lens has a first lens material injection part,
wherein the second lens has a second lens material injection part,
wherein the third lens has a third lens material injection part, and
wherein the first lens material injection part, the second lens material injection part, and the third lens material injection part are at different positions from each other in a plan view.

19. The electronic device of claim 18,
wherein each of the first lens, the second lens, and the third lens is formed by an injection molding process,
wherein the first lens material injection part corresponds to an injection part into which a material forming the first lens is injected in the injection process,
wherein the second lens material injection part corresponds to an injection part into which a material forming the second lens is injected in the injection process,
wherein the third lens material injection part corresponds to an injection part into which a material forming the third lens is injected in the injection process,
wherein a first virtual line passing through a center of the third lens material injection part and a center of the third lens, and a second virtual line passing through a center of the second lens and a center of the second lens form a first angle,
wherein the first virtual line and a third virtual line passing through a center of the first lens material injection part and a center of the first lens form a second angle,
wherein the first angle is 170° to 180°, and
wherein the second angle is 35° to 55°.

20. The electronic device of claim 18,
wherein each of the first lens, the second lens, and the third lens is formed by an injection molding process,
wherein the first lens material injection part corresponds to an injection part into which a material forming the first lens is injected in the injection process,
wherein the second lens material injection part corresponds to an injection part into which a material forming the second lens is injected in the injection process,
wherein the third lens material injection part corresponds to an injection part into which a material forming the third lens is injected in the injection process,
wherein the second lens material injection part is on an opposite side of the third lens material injection part, in a plan view, and
wherein the first lens material injection part is spaced from the third lens material injection part along a periphery of the first lens or the third lens, in a plan view.
